(19) United States
(12) Patent Application Publication
(10) Pub. No.: US 2026/0118585 A1
(43) Pub. Date: Apr. 30, 2026

(54) WAVEGUIDES BASED ON NANOIMPRINT LITHOGRAPHY ON A PHOTONIC WAFER SCALE INTERPOSER

(71) Applicant: Volantis Semiconductor, Inc., Portland, OR (US)

(72) Inventor: Tapabrata Ghosh, San Francisco, CA (US)

(73) Assignee: Volantis Semiconductor, Inc., Portland, OR (US)

(21) Appl. No.: 19/210,116

(22) Filed: May 16, 2025

Related U.S. Application Data
(63) Continuation-in-part of application No. 19/192,587, filed on Apr. 29, 2025.
Application No. 19/192,587 is a continuation-in-part of application No. 19/192,146, filed on Apr. 28, 2025.
Application No. 19/192,146 is a continuation-in-part of application No. 19/189,471, filed on Apr. 25, 2025.
Application No. 19/189,471 is a continuation-in-part of application No. 19/188,057, filed on Apr. 24, 2025.
Application No. 19/188,057 is a continuation-in-part of application No. 19/177,834, filed on Apr. 14, 2025.
Application No. 19/177,834 is a continuation-in-part of application No. 19/093,546, filed on Mar. 28, 2025.
Application No. 19/093,546 is a continuation-in-part of application No. 19/079,851, filed on Mar. 14, 2025.
Application No. 19/079,851 is a continuation-in-part of application No. 19/056,456, filed on Feb. 18, 2025.
Application No. 19/056,456 is a continuation-in-part of application No. 19/023,647, filed on Jan. 16, 2025.
Application No. 19/023,647 is a continuation-in-part of application No. 18/978,188, filed on Dec. 12, 2024.
Application No. 18/978,188 is a continuation-in-part of application No. 18/958,107, filed on Nov. 25, 2024.
Application No. 18/958,107 is a continuation-in-part of application No. 18/940,944, filed on Nov. 8, 2024.
(60) Provisional application No. 63/714,353, filed on Oct. 31, 2024.
(60) Provisional application No. 63/720,216, filed on Nov. 14, 2024.
(60) Provisional application No. 63/750,817, filed on Jan. 29, 2025.
(60) Provisional application No. 63/750,822, filed on Jan. 29, 2025.

(51) Int. Cl. G02B 6/136; G02B 6/12; G03F 7/00

(52) U.S. Cl. CPC G02B 6/136; G02B 6/12004; G03F 7/0002; G03F 7/0005; G02B 2006/12107; G02B 2006/12121

(57) ABSTRACT

Disclosed techniques enable improved wafer-scale integration data transfer. A plurality of waveguides is fabricated within a photonic wafer-scale interposer (PWSI) using a nanoimprint lithography (NIL) process. A first waveguide comprises a first distance. The first distance is greater than an exposure, on the PWSI, of a single photomask reticle. A plurality of chiplets is bonded to a front side of the PWSI. The plurality of chiplets includes a plurality of photonic communication devices. Light is emitted by a first photonic communication device toward a first optical coupler. The emitting is based on data sent from a first chiplet in the plurality of chiplets. The light that was emitted is coupled, by the first optical coupler, to the first waveguide. Data that was sent by the first chiplet is received by a second chiplet. The receiving is based on light that was coupled to the first waveguide.

### RELATED APPLICATIONS

This application is a continuation-in-part of U.S. patent application “Photonic Wafer-Scale Interposer With Mirrors Based on Nanoimprint Lithography” Ser. No. 19/192,587, filed Apr. 29, 2025.

The U.S. patent application “Photonic Wafer-Scale Interposer With Mirrors Based on Nanoimprint Lithography” Ser. No. 19/192,587, filed Apr. 29, 2025, is also continuation-in-part of U.S. patent application “Photonic Wafer-Scale Interposer With Micro Transfer Printed VCSELS And Back Side Power Delivery” Ser. No. 19/192,146, filed Apr. 28, 2025.

The U.S. patent application “Photonic Wafer-Scale Interposer With Micro Transfer Printed VCSELS And Back Side Power Delivery” Ser. No. 19/192,146, filed Apr. 28, 2025 is also a continuation-in-part of U.S. patent application “Photonic Wafer Scale Interposer With Integrated Crystallographic Etched Mirrors And Pre-Angled Light” Ser. No. 19/189,471, filed Apr. 25, 2025.

The U.S. patent application “Photonic Wafer Scale Interposer With Integrated Crystallographic Etched Mirrors And Pre-Angled Light” Ser. No. 19/189,471, filed Apr. 25, 2025, is also a continuation-in-part of U.S. patent application “Photonic Wafer Scale Interposer With Angled Beam Grating Couplers” Ser. No. 19/188,057, filed Apr. 24, 2025.

The U.S. patent application “Photonic Wafer Scale Interposer With Angled Beam Grating Couplers” Ser. No. 19/188,057, filed Apr. 24, 2025, is also a continuation-in-part of U.S. patent application “Back Side Power Delivery For Wafer-Scale Integration With An Isometric Grid Array With Compression Pins” Ser. No. 19/177,834, filed Apr. 14, 2025.

The U.S. patent application “Back Side Power Delivery For Wafer-Scale Integration With An Isometric Grid Array With Compression Pins” Ser. No. 19/177,834, filed Apr. 14, 2025, is also a continuation-in-part of U.S. patent application “Back Side Power Delivery For Wafer-Scale Integration With Laser Assisted Bonding” Ser. No. 19/093,546, filed Mar. 28, 2025.

The U.S. patent application “Back Side Power Delivery For Wafer-Scale Integration With Laser Assisted Bonding” Ser. No. 19/093,546, filed Mar. 28, 2025, is also a continuation-in-part of U.S. patent application “Photonic Wafer-Scale Interposer With Tapered Waveguides” Ser. No. 19/079,851, filed Mar. 14, 2025.

The U.S. patent application “Photonic Wafer-Scale Interposer With Tapered Waveguides” Ser. No. 19/079,851, filed Mar. 14, 2025, is also a continuation-in-part of U.S. patent application “Back Side Power Delivery For Wafer-Scale Integration With An Isometric Grid Compression Plate” Ser. No. 19/056,456, filed Feb. 18, 2025, which claims the benefit of U.S. provisional patent applications “Chiplet-Based Optical Wafer-Scale Network Switch” Ser. No. 63/750,817, filed Jan. 29, 2025, and “Wafer-Scale Integration Power Delivery With An Isotropic Conductive Adhesive” Ser. No. 63/750,822, filed Jan. 29, 2025.

The U.S. patent application “Back Side Power Delivery For Wafer-Scale Integration With An Isometric Grid Compression Plate” Ser. No. 19/056,456, filed Feb. 18, 2025, is also a continuation-in-part of U.S. patent application “Back Side Power Delivery For Wafer-Scale Integration With Solderless Modular Power Substrates” Ser. No. 19/023,647, filed Jan. 16, 2025, which claims the benefit of U.S. provisional patent applications “Cooling For Wafer-Scale Integration With Back Side Power Coupling” Ser. No. 63/714,353, filed Oct. 31, 2024, and “Back Side Wafer-Scale Power Delivery With An Anisotropic Conductive Film” Ser. No. 63/720,216, filed Nov. 14, 2024.

The U.S. patent application “Back Side Power Delivery For Wafer-Scale Integration With Solderless Modular Power Substrates” Ser. No. 19/023,647, filed Jan. 16, 2025 is also a continuation-in-part of U.S. patent application “Wafer-Scale Integration With A Stiffening Isometric Grid Array” Ser. No. 18/978,188, filed Dec. 12, 2024, which claims the benefit of U.S. provisional patent applications “Cooling for Wafer-Scale Integration With Back Side Power Coupling” Ser. No. 63/714,353, filed Oct. 31, 2024, and “Back Side Wafer-Scale Power Delivery With An Anisotropic Conductive Film” Ser. No. 63/720,216, filed Nov. 14, 2024.

The U.S. patent application “Wafer-Scale Integration With A Stiffening Isometric Grid Array” Ser. No. 18/978,188, filed Dec. 12, 2024 is also a continuation-in-part of U.S. patent application “Cold Plate Cooling For Wafer-Scale Integration With Back Side Modular Power Delivery” Ser. No. 18/958,107, filed Nov. 25, 2024, which claims the benefit of U.S. provisional patent applications “Cooling for Wafer-Scale Integration With Back Side Power Coupling” Ser. No. 63/714,353, filed Oct. 31, 2024, and “Back Side Wafer-Scale Power Delivery With An Anisotropic Conductive Film” Ser. No. 63/720,216, filed Nov. 14, 2024.

The U.S. patent application “Cold Plate Cooling For Wafer-Scale Integration With Back Side Modular Power Delivery” Ser. No. 18/958,107, filed Nov. 25, 2024, is also a continuation-in-part of U.S. patent application “Back Side Wafer-Scale Integration With Modular Power Delivery” Ser. No. 18/940,944, filed Nov. 8, 2024, which claims the benefit of U.S. provisional patent application “Cooling for Wafer-Scale Integration With Back Side Power Coupling” Ser. No. 63/714,353, filed Oct. 31, 2024.

Each of the foregoing applications is hereby incorporated by reference in its entirety.

### FIELD OF ART

This application relates generally to transferring data and more particularly to waveguides based on nanoimprint lithography on a photonic wafer-scale interposer.

### BACKGROUND

Processors communicate with various elements to perform processing tasks. There are often three basic processor elements: a central processing unit (CPU), an arithmetic logic unit (ALU), and registers. The CPU executes instructions that can include arithmetic operations such as addition and subtraction, and logical operations such as AND, OR, and XOR. The ALU performs the arithmetic and logical operations on data that can be loaded (read) from the registers, and the results of the operations stored (written) into the registers. The CPU can execute conditional instructions such as if-then-else instructions and can handle exceptions to normal operations. Since the registers typically represent a relatively small amount of storage, the CPU executes memory access operations. These instructions enable the CPU to load data from and store data to memory such as cache memory, shared memory, and system memory. The CPU can further execute instructions that enable communication with a user, a network, and other processors, to name only a few. In order for the CPU to access the other processor elements, memory, networking, and the users who utilize the processor, the processor elements are interconnected by a bus. The bus enables the various elements to communicate and to coordinate instruction execution, among other operations.

A processor typically has more than one bus. The buses include a data bus, an address, and a control bus. The data bus sends and receives data from the various elements. For example, data can be loaded from the memory, operated on by the ALU, and the results can be stored back to memory, typically under control of the CPU. The address bus is used to indicate a register or a memory location from which or to which data is loaded or stored. The control bus is used to synchronize processor operations. The buses associated with the processor include internal buses and external buses. The internal buses include a front side bus that connects the CPU to main memory, a back side bus that enables communication between the CPU and cache memory, and a memory bus that connects the CPU to system memory. The external buses enable connection of the processor to peripherals such as devices external to the processor, networks, and more. These external buses are typified by USB, PCI, and SATA buses.

In order for the processor to successfully operate, the use of the internal buses and the external buses must be coordinated. This coordination is accomplished by bus arbitration. The bus arbitration can be centralized or distributed. The centralized arbitration uses a single arbiter to manage access to the various buses. This centralization can simplify arbitration, but the single arbiter can bog down trying to handle requests from processor elements and peripherals. The distributed arbitration moves the arbitration tasks to the elements and peripherals that access the buses. This latter approach increases control complexity but can better coordinate and expedite bus accesses. Whichever approach is used, successful arbitration of bus accesses is essential to effective processor operation.

### SUMMARY

The doubling the number of transistors in a microchip every two years has more or less held true since Gordon Moore made his prediction in 1965. The doubling is supported by technological advancements, improved processor architectures, and even advanced mathematical techniques. The increased transistor count has greatly bolstered processing power and storage capacity, while reducing processing cost from a per-transistor basis. As a result, users demand ever faster performance from their electronic systems. Beyond hardware performance demands, the applications further drive new circuit designs and architectures for the devices and the applications. Popular and innovative device features also create new technological and architectural improvement demands. These popular features now routinely include biometric authentication, high resolution cameras, and three-dimensional or “spatial” audio. Whether the computers span vast, multisite server farms, or are handheld devices, users are not satisfied with the current state of the art.

The latest processors and applications are significantly faster and more capable than previous generations of both the hardware and the software. Inspired by these advanced systems and software, new ideas for even more complex and computationally intensive applications are rapidly being proposed and developed. The enhanced applications require faster and more capable systems and devices, thus forcing designers and architects to propose, design, and fabricate improved integrated circuits and applications. That said, increased chip performance and added functionality such as AI processing require the addition of significant and complex circuitry. To fit new circuitry into the chips, designers utilize two main design philosophies: increase the physical dimensions of the chip or increase circuit density by reducing circuit feature sizes. These techniques have successfully been implemented to meet the relentless customer demands for increased performance. As a result, processors, graphics processors, AI accelerators, ML accelerators, and so on currently boast transistor counts into the tens of billions. Concomitant with increasing performance, the architectural improvements and added devices increase the power density of the chips, resulting in prodigious heat generation. Thus, provisioning power and removing heat become critical design criteria. Further, because interconnect or wire associated with the chips can become long and narrow as the elements of the chip are interconnected, propagation of data among the various elements of the chip can impose significant performance bottlenecks.

Disclosed techniques enable waveguides based on nanoimprint lithography on a photonic wafer-scale interposer. A plurality of waveguides is fabricated within a photonic wafer-scale interposer (PWSI) using a nanoimprint lithography (NIL) process. A first waveguide within the plurality of waveguides comprises a first distance. The first distance is greater than an exposure, on the PWSI, of a single photomask reticle. A plurality of chiplets is bonded to a front side of the PWSI. The plurality of chiplets includes a plurality of photonic communication devices. Light is emitted by a first photonic communication device, within the plurality of photonic communication devices, toward a first optical coupler. The emitting is based on data sent from a first chiplet in the plurality of chiplets. The light that was emitted is coupled, by the first optical coupler, to the first waveguide. Data that was sent by the first chiplet is received by a second chiplet within the plurality of chiplets. The receiving is based on light that was coupled to the first waveguide.

A method for transmitting data is disclosed comprising: fabricating, using a nanoimprint lithography (NIL) process, a plurality of waveguides within a photonic wafer-scale interposer (PWSI), wherein a first waveguide within the plurality of waveguides comprises a first distance, wherein the first distance is greater than an exposure, on the PWSI, of a single photomask reticle; bonding, to a front side of the PWSI, a plurality of chiplets, wherein the plurality of chiplets includes a plurality of photonic communication devices; emitting light, by a first photonic communication device within the plurality of photonic communication devices, toward a first optical coupler, wherein the emitting is based on data sent from a first chiplet in the plurality of chiplets; coupling, by the first optical coupler, the light that was emitted, to the first waveguide; and receiving, by a second chiplet within the plurality of chiplets, data that was sent by the first chiplet, wherein the receiving is based on light that was coupled to the first waveguide.

Various features, aspects, and advantages of various embodiments will become more apparent from the following further description.

### BRIEF DESCRIPTION OF THE DRAWINGS

The following detailed description of certain embodiments may be understood by reference to the following figures wherein:

FIG. 1 is a flow diagram for waveguides based on nanoimprint lithography on a photonic wafer-scale interposer.

FIG. 2 is a flow diagram for providing power.

FIG. 3 illustrates an interposer and flip-chips for wafer-scale integration.

FIG. 4 is a diagram of a waveguide.

FIG. 5 is a diagram of a reticle.

FIG. 6 is an example of nanoimprint lithography (NIL).

FIG. 7 is a cross-section of a photonic wafer-scale interposer (PWSI).

FIG. 8 is a diagram of a grating coupler.

FIG. 9 is an apparatus for transmitting data.

FIG. 10 is a system diagram for waveguides based on nanoimprint lithography on a photonic wafer-scale interposer.

### DETAILED DESCRIPTION

Techniques for transmitting data using waveguides based on nanoimprint lithography on a photonic wafer-scale interposer are disclosed. Advanced and evolving, computationally intensive applications require significant improvements to processing performance. The processing improvements are based on significantly increased numbers of transistors that have been added to a wide variety of modern chiplets and system-on-chips (SoCs). The chiplets can include processors, memories, switching elements, and so on. SoCs can include modules or cores such as processors, multiprocessors, memories, input/output (I/O) circuits, network switches, and other elements. The SoCs can be dimensionally large, possessing tens of billions of transistors. Concurrently, feature sizes of elements within the SoCs continue to shrink. The design approach of keeping chip sizes roughly the same size while increasing transistor count with smaller transistors is generally good news. However, new technologies that enable the smaller transistors impose many significant new design challenges. Among the challenges are increased leakage currents, resulting in higher power consumption and increased heat dissipation for the chip. The leakage currents, in combination with the active power requirements, can drive extremely high-power densities for processors and other computing elements. Further, the wafers on which these large chips are fabricated are delicate. The wafers can fracture if the wafers are not properly handled and supported during fabrication, packaging, deployment, etc.

Massive, computationally intensive applications have spurred a keen interest in developing design techniques that enable wafer-scale integration. In wafer-scale integration, a single chip is fabricated on an entire wafer. While laudable, because of physical defects distributed randomly across a wafer, circuitry fabricated on the defects will likely not perform as expected, if at all. Instead, the technique based on using an interposer has been developed. Here, circuits such as chiplets are bonded to the interposer. However, in high performance applications, chiplets may need to communicate with other chiplets located a long distance away on the interposer. Standard wiring techniques, even with additional widths and/or thickness, can continue to be a performance limiting factor due to high RC delays. As a result, designers may be forced to introduce latches, flip-flops, staging, etc. which can result in performance bottlenecks. Waveguides have been proposed in order to accomplish high speed data communications with wafer-scale integration techniques. Such waveguides can be fabricated into the wafer with standard lithography techniques. However, for long communication paths, these waveguides can extend beyond a single reticle used for lithography. Other techniques such as reticle stitching can be used to build longer waveguides. However, these techniques require precise alignment between reticles. Misalignments can cause defects, increased crosstalk, increased parasitics, and/or optical losses which can compromise the integrity of the waveguide, result in lower yields, or result in unsustainable optical losses, especially for longer waveguide paths that can be “stitched” across multiple reticles for cross-wafer communication.

To address the technical challenges, while enabling high-speed data communications within the wafer-scale integration interposer described above, waveguides based on nanoimprint lithography on a photonic wafer-scale interposer are disclosed. A plurality of waveguides is fabricated within a photonic wafer-scale interposer (PWSI) using a nanoimprint lithography (NIL) process. A first waveguide within the plurality of waveguides comprises a first distance. The first distance is greater than an exposure, on the PWSI, of a single photomask reticle. A plurality of chiplets is bonded to a front side of the PWSI. The plurality of chiplets includes a plurality of photonic communication devices. Light is emitted, by a first photonic communication device within the plurality of photonic communication devices, toward a first optical coupler. The emitting is based on data sent from a first chiplet in the plurality of chiplets. The light that was emitted is coupled, by the first optical coupler, to the first waveguide. Data that was sent by the first chiplet is received by a second chiplet within the plurality of chiplets. The receiving is based on light that was coupled to the first waveguide.

A plurality of modular power substrates (MPSs) can be coupled to a back side of the PWSI. The coupling can be accomplished using one or more elastomer sheets. The plurality of MPSs can be coupled to a unified control board (UCB). The coupling can include compressing the PWSI. The compressing can be based on coupling an isometric grid array (IGA) to a cold plate. The cold plate can remove a portion of excess heat generated by the plurality of chiplets. The coupling can be based on one or more spring-loaded fasteners, one or more clamps, and so on. The fasteners can be configured to provide a desired amount of compression. The compressing can maintain a coplanarity of the PWSI. The coupling can be based on a plurality of sockets. The UCB includes a plurality of DC-to-DC power converters. The coupling the MPSs can couple each MPS within the plurality of MPSs to one or more chiplets within the plurality of chiplets. The MPSs can provide power to the one or more chiplets and other electronic elements. The chiplets to which power is provided can exchange data with waveguides based on nanoimprint lithography. Light from one or more photonic communication devices can be coupled to one or more waveguides.

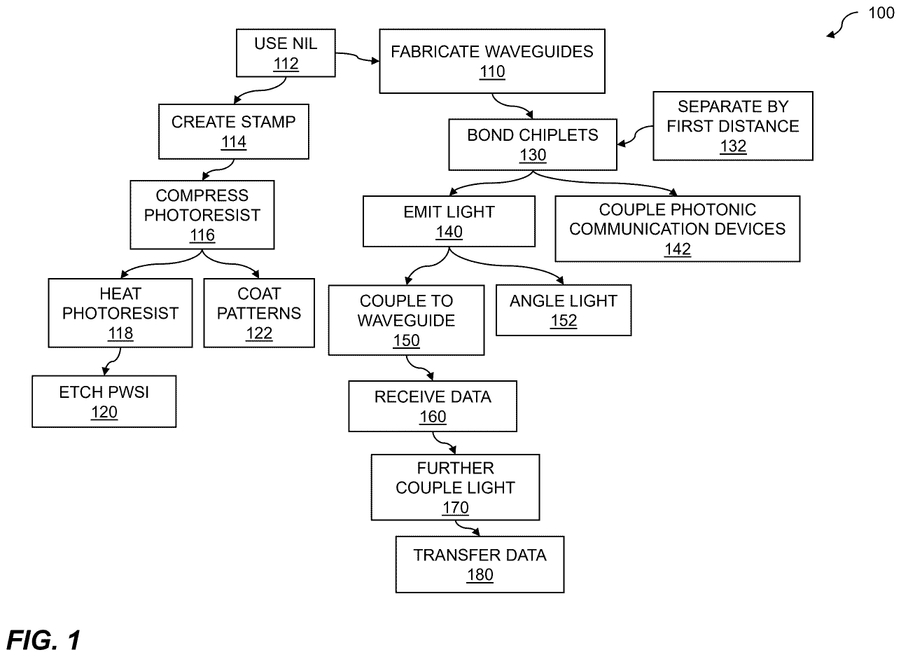

FIG. 1 is a flow diagram for waveguides based on nanoimprint lithography on a photonic wafer-scale interposer. The flow 100 comprises fabricating 110, using a nanoimprint lithography (NIL) process, a plurality of waveguides within a photonic wafer-scale interposer (PWSI), wherein a first waveguide within the plurality of waveguides comprises a first distance, wherein the first distance is greater than an exposure, on the PWSI, of a single photomask reticle. For some lithography applications such as those associated with large scale integration (VLSI) circuit design, a technique such as reticle stitching can be used, where reticles can be carefully aligned in order to fabricate circuits that are larger than can be fabricated using a single reticle. The plurality of waveguides can be fabricated based on a variety of semiconductor fabrication technologies. Here, the first waveguide includes a distance that is greater than can be exposed using a single reticle. In embodiments, the fabricating does not include reticle stitching. In a usage example, the plurality of waveguides can be fabricated in a silicon-on-insulator (SOI) technology (discussed below). The plurality of waveguides can be used to send data between chiplets within a plurality of chiplets bonded to a front side of the PWSI.

The flow 100 comprises using a nanoimprint lithography (NIL) process 112. The NIL process can be used to build plurality of waveguides within a portion of the PWSI. In embodiments, the NIL process comprises a full-wafer nanoimprint process. The NIL process can include forming structures, such as waveguides, across an entire wafer, allowing for structures that are larger than a single mask or reticle to be formed. The nanoimprinted waveguides can be used to send light from a first chiplet to a second chiplet. The light can be emitted by a photonic communication device (described below). The photonic communication devices can include light sources, optical detectors, optical receivers, and so on. The PWSI within which the waveguides can be fabricated using the NIL process can be configured for a variety of processing applications such as audio and voice processing, image and video processing, artificial intelligence (AI), switching, machine learning (ML), and so on. In embodiments, the PWSI comprises an optical wafer-scale AI accelerator, wherein one or more chiplets within the plurality of chiplets comprise one or more artificial intelligence (AI) accelerators. The AI accelerators can be configured to process a variety of AI models that can be based on networks such as convolutional neural networks (CNNs). In other embodiments, the PWSI comprises an optical wafer-scale network switch, wherein one or more chiplets within the plurality of chiplets comprise one or more switching chiplets. The optical wafer-scale network switch can be configured to transfer large datasets such as datasets associated with search, AI and ML processing, etc. The optical wafer-scale network switch can be based on various network topologies such as a star topology, mesh topology, ring topology, HyperX topology, and so on.

The fabricating the plurality of waveguides can be accomplished using a variety of fabrication techniques. In the flow 100, the fabricating includes creating a stamp 114, wherein the stamp includes one or more topological patterns, wherein the one or more topological patterns correspond to the plurality of waveguides. The stamp can include a hard stamp, where the hard stamp can be based on silicon, quartz (SiO2), and so on. The stamp can include a soft stamp, where the soft stamp can be based on a polymer. The flow 100 further comprises compressing 116, by the stamp, photoresist deposited on the PWSI, wherein the compressing results in an imprint of the plurality of topological patterns in the photoresist. The topological patterns in the photoresist can indicate which structures such as the nanoimprint mirrors will be formed. In the flow 100, the compressing includes heating 118 the photoresist. The heating the photoresist can cause the photoresist to cure or harden. The cured photoresist can enable or block further building steps associated with building the nanoimprinted waveguides, such as a first waveguide. The flow 100 comprises etching 120 the PWSI. The etching can be accomplished using a “wet” etch based on liquid chemicals or can be accomplished using a “dry” etch. A dry etch can be based on a high-energy plasma that selectively removes material from the substrate. The flow 100 further comprises coating 122 the one or more topological patterns, wherein the coating results in a cladding of the first waveguide. The cladding surface can be based on aluminum alloys, alternating layers of molybdenum and silicon, etc. The cladding can confine light within a waveguide by enhancing internal reflection of the waveguide. The internal reflection minimizes an amount of light that can escape from the waveguide.

The flow 100 comprises bonding 130, to a front side of the PWSI, a plurality of chiplets, wherein the plurality of chiplets includes a plurality of photonic communication devices. The chiplets can include processing chiplets, memory chiplets, AI accelerator chiplets, switching chiplets, I/O chiplets, and so on. The photonic communication devices can include emitters, couplers, detectors, and so on. The chiplets can include a first chiplet within the plurality of chiplets and a second chiplet within the plurality of chiplets. In a usage example, the chiplets can include AI accelerator chiplets or switching chiplets. Recall that a first distance can comprise a distance greater than an exposure, on the PWSI, of a single photomask reticle. In the flow 100, the first chiplet and the second chiplet are separated 132, on the PWSI, by substantially the first distance. The first chiplet and the second chiplet can communicate using a waveguide that comprises the first distance. As described earlier, the waveguide can be built with NIL to avoid issues (explained above) that can result from a reticle stitching fabrication process.

The flow 100 includes emitting light 140, by a first photonic communication device within the plurality of photonic communication devices, toward a first optical coupler, wherein the emitting is based on data sent from a first chiplet in the plurality of chiplets. The first photonic communication device can include a light emitting device. In embodiments, the first photonic communication device comprises a surface-emitting light source. The surface-emitting light source can include a variety of light sources. In embodiments, the first photonic communication device comprises a vertical-cavity surface-emitting laser (VCSEL). A surface-emitting light source can further include an LED light source, a laser diode (LD) light source, etc. In other embodiments, the first photonic communication device comprises a ring resonator. A ring resonator can be based on a circular waveguide. When light at a particular wavelength is introduced to the circular waveguide, constructive interference occurs between the light in the circular waveguide and the introduced light. The constructive interference can create sharp resonance peaks within the waveguide.

In the flow 100, the bonding includes coupling 142 the first photonic communication device to the PWSI, wherein the coupling is based on micro-transfer printing. The bonding can accomplish mechanical coupling and/or electrical coupling of the first photonic communication device and other photonic communication devices to the PWSI. A variety of techniques can be used to accomplish the coupling of the communication devices. In a usage example, the bonding is based on benzocyclobutene (BCB). The BCB can be used as an adhesive to bond the communication devices to the PWSI. In another usage example, the bonding is based on fusion bonding. The fusion bonding technique can be based on direct chemical bonds between surfaces of the one or more photonic communication devices (e.g., one or more VCSELs) and the PWSI. In a further usage example, bonding the photonic communication devices that were deposited, to the PWSI, is accomplished using laser-assisted bonding (LAB). The LAB technique uses a laser to provide localized heating to solder connections such as solder balls, C4s, microbumps, and so on. The localized heating enables melting the solder balls, leaving adjacent materials and structures unheated and unaffected.

Recall that light can be emitted by a first photonic communication device toward a first optical coupler. The flow 100 includes coupling, by the first optical coupler, the light 150 that was emitted, to the first waveguide. The emitted light from a source such as a surface-emitting light source can be coupled to the first waveguide using a variety of techniques. The coupling can be accomplished using a lens, a mirror, a curved waveguide, and so on. In embodiments, the first optical coupler comprises a grating coupler. The grating coupler can include a periodic structure that can be formed within the PWSI. The grating coupler can diffract the emitted light into an inlet aperture of the waveguide. The waveguide can include a waveguide fabricated within the PWSI using a nanoimprint lithography (NIL) process. The flow 100 includes angling the light 152 that was emitted by the first photonic communication device, wherein the angling is based on a micro-optical element (MOE). The first photonic communication device can include a surface-emitting light source. In embodiments, the first photonic communication device comprises a vertical-cavity surface-emitting laser (VCSEL). By angling the light from the first photonic communication device such as the surface-emitting light source, the emitted light, when coupled by the first optical coupler, can be directed into the waveguide at an angle substantially normal to the input or entrance aperture of the waveguide. In a usage example, the angling is based on a location of the at least one photonic communication device, wherein the angling compensates for cross-wafer variation. The cross-wafer variation can be due to wafer warpage, wafer processing variations, etc.

The flow 100 comprises receiving 160, by a second chiplet within the plurality of chiplets, data that was sent by the first chiplet, wherein the receiving is based on light that was coupled to the first waveguide. The data that is received by the second chiplet can include electronic data such as serial electronic data. The electronic data can be generated by converting the optical data that is received via the waveguide to electronic data. In a usage example, the converting the optical data that is received can be accomplished using a photodiode or similar device.

In the flow 100, the receiving comprises further coupling 170 the light that was coupled to the first waveguide, by a second optical coupler, from the first waveguide, to an optical receiver. The second optical coupler can include a coupler that couples light from the first waveguide to an optical receiver coupled to the PWSI. The optical receiver can convert the optical data, such as optical serial data, to electronic data, such as serial electronic data. The second optical coupler can include an electro-optical element. In embodiments, the second optical coupler comprises a photodiode. The photodiode can reproduce the sent electronic data by converting the optical data from the waveguide to electronic data. The flow 100 further comprises transferring 180, by the optical receiver, the data to a second chiplet. The transferring can be accomplished using one or more interconnect layers associated with the PWSI.

Embodiments include providing power to the plurality of chiplets, wherein the providing is based on a back side of the PWSI, and wherein the PWSI includes a plurality of through-silicon vias (TSVs). In order for the power to reach the chiplets, light sources, and other elements, the power can be provided from the back side of the PWSI to the front side of the PWSI using the plurality of TSVs. Embodiments include coupling, to the back side of the PWSI, a plurality of modular power substrates (MPSs). The plurality of MPSs can deliver power such as DC power. Embodiments include coupling the plurality of MPSs to a unified control board (UCB), wherein the coupling is based on a plurality of sockets, and wherein the UCB includes a plurality of DC-to-DC power converters. The UCB can deliver DC power. Embodiments can include delivering DC power, by the UCB, to the plurality of chiplets, wherein the delivering is based on the plurality of DC-to-DC power converters, the plurality of MPSs, and the plurality of TSVs, and wherein the delivering includes a first voltage conversion. The delivering DC power can be accomplished by coupling one or more DC-to-DC converters to one or more MPSs. Interconnection between the DC-to-DC converters matched with one or more respective MPSs can be accomplished using interconnect associated with the UCB. The DC power that is delivered can include a range for the DC voltage. The range of DC voltage can include a percentage of a target voltage, an allowable operating range of DC voltage, and the like. In a usage example, the voltage range can include 48 volts to 54 volts, inclusive. The delivering can include a first voltage conversion.

Embodiments include transferring the DC power from the UCB, by the plurality of MPSs, to the plurality of chiplets, wherein the transferring includes a second voltage conversion. The plurality of chiplets can obtain the transferred power using interconnect, contacts, and so on. The chiplets and other electronic elements can also use interconnect and contacts to receive and send data, instructions, control signals, etc. The second voltage conversion can be accomplished using one or more converters such as DC-to-DC converters associated with the MPSs. The second voltage conversion can produce a voltage that can be used directly to operate one or more chiplets. The second voltage conversion can attain a voltage less than the voltage resulting from the first voltage conversion. The second voltage conversion can result in a voltage less than a threshold. The threshold can include a target voltage, an operating voltage, and so on. In a usage example, the threshold is 1 volt. The transferring is based on the plurality of TSVs. The transferring can include transferring DC power, receiving and sending data, sending and receiving functional chip instructions and control signals, etc.

Various steps in the flow 100 may be changed in order, repeated, omitted, or the like without departing from the disclosed concepts. Various embodiments of the flow 100, or portions thereof, can be included in an apparatus for transferring data or system that is configured to transfer data.

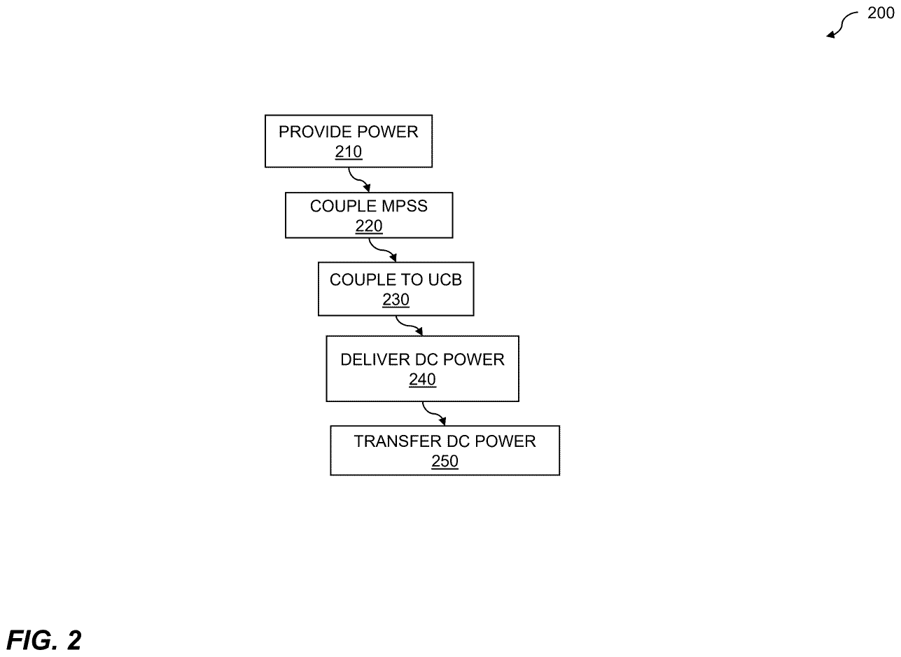

FIG. 2 is a flow diagram for providing power. The providing power can enable operation of active electronic elements. Integrated circuits or chips such as chiplets, photonic communication devices such as surface-emitting light sources, functional chips, and so on can be bonded, mounted, or otherwise coupled to a photonic wafer-scale interposer (PWSI). The coupling can be accomplished using solder bumps such as micro-bumps, controlled collapse chip connections (C4s), and the like. The use of the PWSI supports wafer-scale integration (WSI), which is particularly useful to supporting the processing requirements of computationally intensive applications such as artificial intelligence (AI) acceleration, machine learning (ML) applications, natural language (NL) applications, etc. The chiplets that can enable high-speed communication such as data transfers using photonic communication devices such as vertical-cavity surface-emitting lasers (VCSELs), waveguides, and the chiplets that execute the computationally intensive applications can require significant amounts of power during operation. The power, which includes DC power, must be provided to the chiplets, the light sources, functional chips, etc. The power can be provided using modular power delivery techniques. At least a portion of the generated heat can be transferred to a cold plate, where the heat can be transferred to a coolant that can be circulated through the cold plate, a heat exchanger, etc. Thus, providing DC power via back side power delivery supports the use of waveguides based on nanoimprint lithography on a photonic wafer-scale interposer. The PWSI can include a 300 mm wafer, a 200 mm wafer, or a wafer of another size.

The flow 200 includes providing power 210 to the plurality of chiplets, wherein the providing is based on a back side of the PWSI, and wherein the PWSI includes a plurality of through-silicon vias (TSVs). The providing power can include providing DC power. The chiplets, photonic communication devices, functional chips, controllers, etc. require power such as DC power to operate. The power can be provided by coupling one or more power modules (described below) to a back side of the PWSI. In order for the power to reach the chiplets, light sources, and other elements, the power can be provided from the back side of the PWSI to the front side of the PWSI using the TSVs.

The flow 200 includes coupling 220, to the back side of the PWSI, a plurality of modular power substrates (MPSs). The coupling can be accomplished using a variety of techniques. In embodiments, the coupling can be based on a plurality of elastomer sheets. The elastomer sheets can include conducting filaments. The conducting filaments can provide a conduction path from a front side of an elastomer sheet to a back side of the elastomer sheet. The conducting fibers can include carbon fibers, graphene fibers, metal fibers such as copper fibers or silver fibers, and so on. In other embodiments, the coupling can be based on a laser-assisted bonding (LAB) technique. Using LAB, solder balls, such as microbumps and C4s, can be melted using a laser. The melting the solder balls using a laser tightly concentrates heating to the solder balls while leaving materials adjacent to the solder balls unheated. Thus, previous fabrication steps such as diffusion, soldering, and so on remain unheated and thereby unaffected. In a usage example, each MPS within the plurality of MPS can be inserted into an isometric grid array (IGA). The IGA can maintain a coplanarity of the PWSI, where coplanarity of the PWSI enables reliable electrical and mechanical couplings between the plurality of MPSs and the PWSI. The PWSI can be delicate and prone to cracking and breaking due to its thinness. The IGA further supports the PWSI, thereby reducing risk to the PWSI while handing the PWSI and while the PWSI is in operation.

The flow 200 includes coupling 230 the plurality of MPSs to a unified control board (UCB), wherein the coupling is based on a plurality of sockets, and wherein the UCB includes a plurality of DC-to-DC power converters. The coupling can be accomplished using plug-and-socket connectors, terminals, pins, cables, jumpers, and so on. Noted previously and throughout, power such as DC power must be delivered to the chiplets bonded to the front side of the PWSI in order for the chiplets to operate. The DC power must also be delivered to other elements coupled to the PWSI, such as the one or more digital controller chips, photonic communication devices such as surface-emitting light sources, functional chips, and so on. Embodiments can include providing power such as DC power to the plurality of chiplets. In a usage example, the coupling the plurality of MPSs to the UCB can be accomplished using DC power connectors associated with the plurality of MPSs and the plurality of sockets associated with the UCB. The coupling can further be accomplished using a plurality of rigid-flex strips. The rigid-flex strips can carry control signals from one or more digital controllers (see below) which can control the flow of DC power to the chiplets from the MPSs and/or the UCB. The coupling can be based on a high voltage socket. The UCB can include other chips, chiplets, and so on. The UCB can include one or more digital controller chips to control the DC-to-DC power converters. The digital controller chips can comprise one or more of a processor, a multiprocessor, a microcontroller, and so on. The one or more digital controller chips can control the DC-to-DC power converters.

The flow 200 includes delivering DC power 240, by the UCB, to the plurality of chiplets, wherein the delivering is based on the plurality of DC-to-DC power converters, the plurality of MPSs, and the plurality of TSVs, and wherein the delivering includes a first voltage conversion. The delivering DC power can include delivering DC power to a subset of MPSs. The delivering DC power can be accomplished by coupling one or more DC-to-DC converters to one or more MPSs. Interconnection between the DC-to-DC converters matched with one or more respective MPSs can be accomplished using interconnect associated with the UCB. The DC power that is delivered can include a range for the DC voltage. The range of DC voltage can include a percentage of a target voltage, an allowable operating range of DC voltage, and the like. In a usage example, the voltage range can include 48 volts to 54 volts, inclusive. The delivering can include a first voltage conversion.

The flow 200 further includes transferring 250 the DC power from the UCB, by the plurality of MPSs, to the plurality of chiplets, wherein the transferring includes a second voltage conversion. The plurality of chiplets can obtain the directed power using interconnect associated with the PWSI, contacts, through-silicon vias (TSVs), and so on. The chiplets and other electronic elements can also use interconnect and contacts to receive and send data, instructions, control signals, etc. The second voltage conversion can be accomplished using one or more converters such as DC-to-DC converters associated with the MPSs. The second voltage conversion can produce a voltage that can be used directly to operate one or more chiplets. The second voltage conversion can attain a voltage less than the voltage resulting from the first voltage conversion. The second voltage conversion can result in a voltage less than a threshold. The threshold can include a target voltage, an operating voltage, and so on. In a usage example, the threshold is 1 volt. The transferring is based on the plurality of TSVs. The transferring can include transferring DC power, receiving and sending data, sending and receiving functional chip instructions and control signals, etc.

Various steps in the flow 200 may be changed in order, repeated, omitted, or the like without departing from the disclosed concepts. Various embodiments of the flow 200, or portions thereof, can be included in an apparatus for transferring data or system that is configured to transfer data.

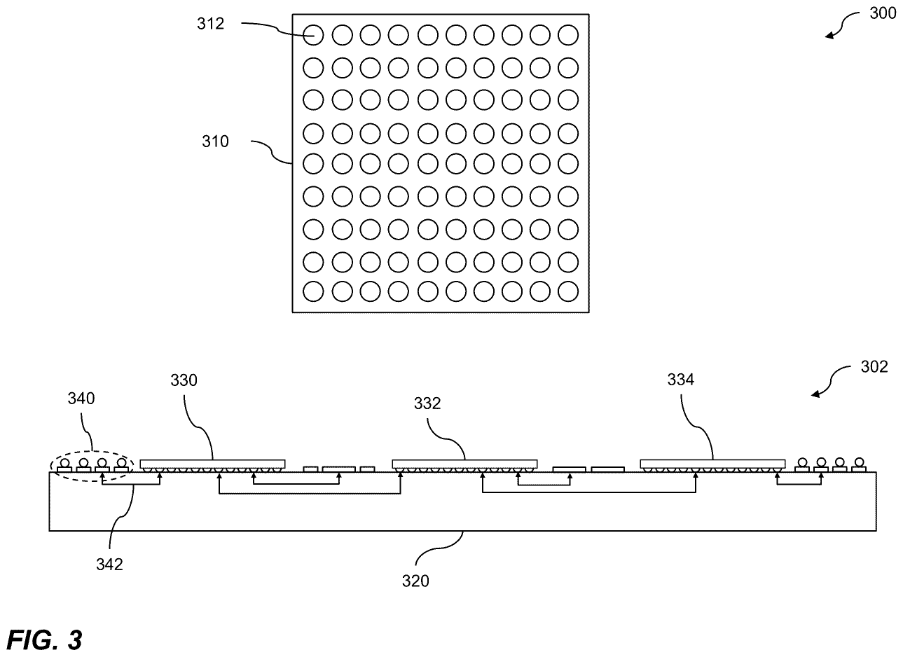

FIG. 3 illustrates an interposer and flip-chips for wafer-scale integration. A technique that approaches the benefits attainable by wafer-scale integration is to couple more than one chip to a common substrate or interposer. The interposer, as shown here, can include a photonic wafer-scale interposer (PWSI). The substrate can include a wafer, a carrier, a circuit board, and so on. To accomplish such a technique, all interconnections to a circuit or chip, including data connections, control and signal connections, power connections, and so on, can be made at the top layer of the chip, rather than at the traditional periphery of the chip. To couple the top connections of the chip to the interposer, solder balls are placed on the top connections and the chip is inverted or “flipped.” The solder balls, when melted, can couple the top connections of the chip to corresponding connections or pads on the interposer. Further chips can be similarly flipped and coupled to additional corresponding connections on the interposer. One challenge to the flip-chip technique is providing power to the chips. The power can be provided using back side power delivery, where power is provided from a back side of the interposer. Another challenge to the flip-chip technique is providing high-speed communications for sending data between and among chips coupled to the interposer. The data from a first chiplet can be converted from electronic data to optical data using a photonic communication device. The photonic communication device can include a surface-emitting light source such as a vertical-cavity surface-emitting laser (VCSEL). The light from the VCSEL can be coupled to a waveguide within the PWSI using a mirror, a grating, and so on. The waveguide is fabricated within the PWSI using a nanoimprint lithography (NIL) process. The light sent through the waveguide can be received by a second chiplet.

The sending data can be enabled using waveguides based on nanoimprint lithography on a photonic wafer-scale interposer. A further challenge to the flip-chip technique is that the aggregate weight of the flipped chips can pose a risk to the delicate wafer or interposer. The wafer can be stiffened using a grid such as an isometric grid array (IGA) in order to protect the wafer from the weight of the flipped chips and other elements. The wafer can further be stiffened using a plurality of reinforcement structures. The plurality of reinforcement structures can enable planar compression of each elastomer sheet within a plurality of elastomer sheets. The elastomer sheets enable coupling of elements such as a plurality of modular power substrates (MPSs) to a back side of a photonic wafer-scale interposer (PWSI). The PWSI can include tapered waveguides.

The FIG. 300 includes an example flip-chip. Discussed previously, the flip-chip 310 differs from a traditional chip in that the connections to the flip-chip are made at the top of the chip rather than to pads located at the periphery of the chip. A top view of a flip-chip is shown. The top can include pads that can be coupled to corresponding pads on a multi-chip module, a circuit board, an interposer, and so on. An example contact or pad 312 is shown. Multiple pads can be distributed across the top of the flip-chip. The pads can be oriented to correspond with receiving pads on the interposer. The orientation of the pads can include an array of pads as shown. In a usage example, a subset of pads can be required to couple the flip-chip to the interposer. Thus, required pads are present at the top of the flip-chip, while the unused pads can be omitted from the top of the flip-chip.

The illustration 302 shows an example interposer. As discussed previously, the interposer 320 can include a wafer, a carrier, a circuit board, and so on. One or more flip-chips can be coupled to the interposer. In the figure, the flip-chips can include a first flip-chip 330, a second flip-chip 332, a third flip-chip 334, and so on. While three flip-chips are shown, other numbers of flip-chips can be coupled to the interposer. In a usage example, the flip-chips can be coupled to the interposer in a grid pattern. In addition to serving as a placement location for the flip-chips, the interposer can provide interconnect. The interconnect can be used to provide signals such as control signals, data, and so on to the flip-chips. The interconnect can further provide power to the flip-chips. Depending on the interposer used to receive the flip-chips, the interposer can include one or more layers of interconnect. The interconnect can include interconnect at a top surface of the interposer such as top surface interconnect 340. The interposer can further include additional layers of interconnect. The additional layers of interconnect can be fabricated on the interposer. The additional layers of interconnect can be isolated from each other using an insulating layer between the conducting interconnect layers. An example “lower layer” connection 342 is shown.

The use of flip-chips coupled to an interposer can enable multichip module (MCM) techniques. A multichip module can refer to a substrate, carrier, circuit board, interposer, etc. onto which multiple ICs can be placed. The multiple ICs can be coupled to the interposer, and the multiple ICs can be wired together using interconnect provided by the interposer. The interconnect associated with the interposer can provide power, control signals, and data between and among the ICs that are coupled to the interposer. The power can be provided using modular power techniques. Depending on the particular type of MCM, the interposer can further include discrete components such as discrete resistors, discrete capacitors, discrete inductors, discrete diodes, discrete transistors, etc. A principal advantage of using MCMs is that multiple electronic components can be enclosed in a single “chip,” thereby improving modularity of a system design. Further, the use of MCMs can improve IC yields compared to ICs produced using monolithic IC design methodologies.

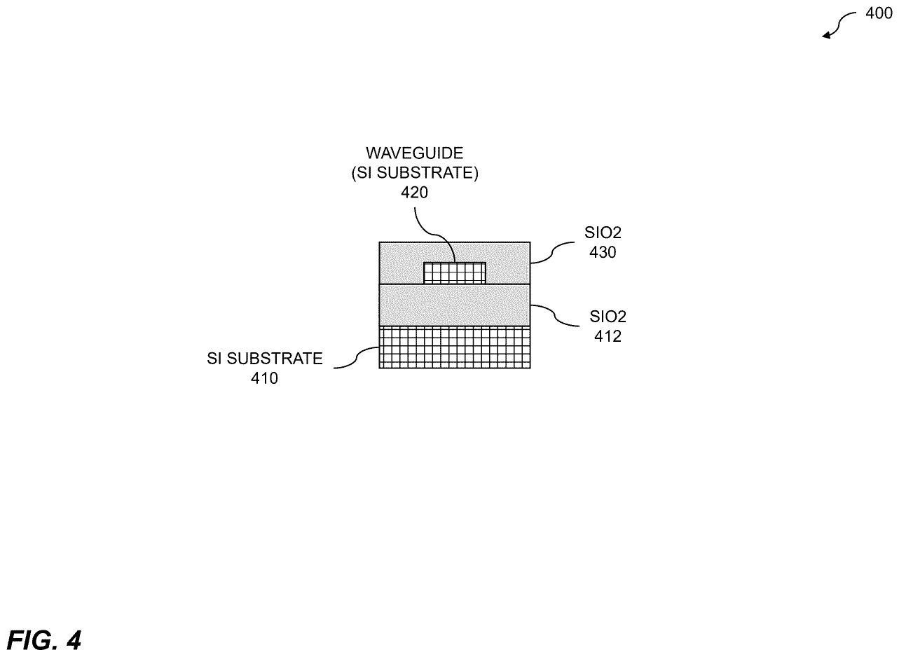

FIG. 4 is a diagram of a waveguide. The waveguide is shown in cross-section. The waveguide can include a waveguide within a plurality of waveguides within an interposer. In embodiments, the waveguide is based on a nanoimprint lithography process on a photonic wafer-scale interposer. The waveguide can be fabricated in a technology such as a Silicon-on-Insulator (SOI) technology. A waveguide can be used to transfer a signal such as an optical signal between two elements such as chiplets. The elements can include switching chiplets. The switching chiplets can be associated with a switch such an optical wafer-scale network switch. The waveguide can be fabricated within a monolithic wafer which includes one or more functional chips. The waveguide can be fabricated within a photonic wafer-scale interposer (PWSI), where the PWSI can be based on a wafer such as a silicon wafer, a glass wafer, and so on. The wafer can be used as a substrate for the PWSI. A plurality of waveguides can be fabricated within the PWSI in order to enable high speed, high bandwidth communication between chiplets. The communication between chiplets can include chiplets separated by a long distance on the PWSI. The waveguides can be tapered. The plurality of nanoimprint lithography waveguides enables transferring data on a photonic wafer-scale interposer.

The figure includes a cross-section of an example waveguide. The example waveguide can be fabricated in a Silicon-on-Insulator (SOI) technology as shown 400, or in another fabrication technology. A silicon substrate 410 is used. The silicon substrate can include a silicon wafer, where the silicon wafer can include a 200 mm silicon wafer, a 300 mm silicon wafer, and so on. A silicon dioxide (insulator) layer 412 can be grown, deposited, or otherwise formed on the silicon wafer. One or more waveguides, such as waveguide 420, can be formed on the insulator layer 412. Any number of waveguides can be formed on the insulator layer 412. An insulator layer 430 can be placed over the one or more waveguides. The insulator layer 430 can be planarized in order to enable fabrication of further elements. The waveguide can conduct light in order to establish optical communications between an optical source and an optical receiver within the PWSI. The waveguide can be utilized by a first chiplet such as a switching chiplet. The first chiplet can send data to a first surface-emitting light source such as a vertical-cavity surface-emitting laser (VCSEL). The VCSEL can convert the data from the first chiplet into optical data. The optical data can be coupled to a waveguide using an optical coupler such as a mirror fabricated using a nanoimprint lithography technique. A second optical coupler can couple light sent through the waveguide and can transfer the optical data to a second chiplet.

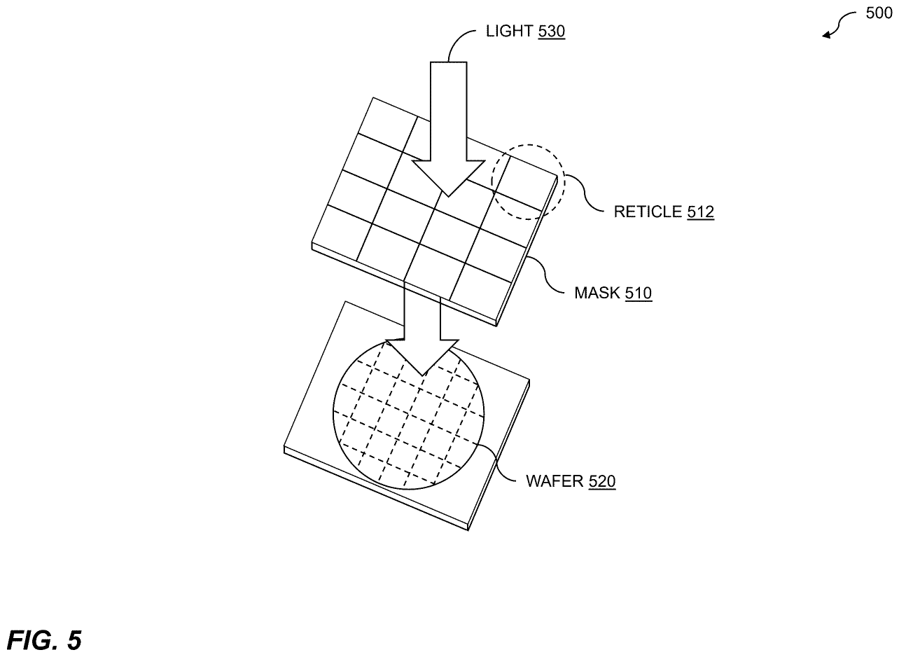

FIG. 5 is a diagram of a reticle. A reticle is used to transfer a pattern based on various processes, where the processes can include a photolithographic process, a nanoimprint lithography process, and so. The reticle can be used to transfer a pattern for fabrication applications such as VLSI circuit design for implementing chiplets, functional chips, SoCs, and so on. The reticle, which can include a portion of or all of a photomask, is typically one of a plurality of reticles used to fabricate a chiplet, SOC, or functional chip; a structure such as a transistor or a wire; and so on. Each reticle is used to transfer a specific pattern to a wafer. The pattern can be associated with a circuit layer within the VLSI circuit design, such as a diffusion layer, a polysilicon layer, a metal layer, a contact or via layer, an implantation layer, an etching mask, and so on.

The diagram 500 shows an example reticle used to transfer a pattern to a wafer using light. The figure includes a mask 510. The mask can include one or more patterns, where the patterns can be represented by one or more reticles. An example reticle 512 within the mask is shown. The mask can be used by implementing a step-and-repeat technique. That is, the mask can be repeatedly used to transfer a pattern, then advanced and used again to transfer the same pattern. The step and repeat technique enables fabricating larger, more complex circuits, fabricating multiple copies of the same circuit, etc. The pattern within each of one or more reticles associated with the mask is transferred to a wafer 520. A material such as photoresist can be deposited onto the wafer prior to exposure to the mask. The photoresist can include a positive photoresist which copies the pattern, or a negative photoresist which copies the negative or opposite of the mask. The exposure of the photoresist through the mask can be accomplished using a light source 530. The light can include deep ultraviolet (DUV) light, extreme ultraviolet (EUV) light, and so on. Once exposed, the photoresist is cured using heat, light such as ultraviolet (UV) light, and so on. The uncured photoresist can be removed, and a processing step such as an etching step can proceed. Wafers, including wafer-scale integration components such as waveguides, can be fabricated with the above techniques. Waveguides that extend beyond a single reticle can be stitched together. However, as described above, reticle stitching can lead to issues such as misalignment which can impact the efficiency and functionality of fabricated waveguides. Disclosed embodiments include fabricating waveguides, including waveguides that cross reticle boundaries, with nanoimprint technology. In embodiments, the fabricating does not include reticle stitching. In embodiments, the NIL process comprises a full-wafer nanoimprint process.

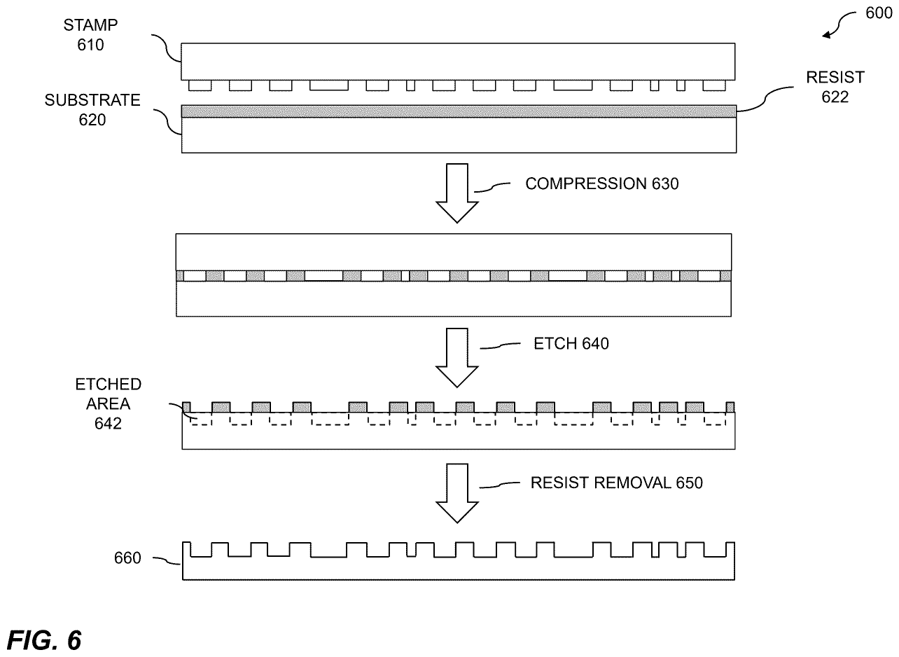

FIG. 6 is an example of nanoimprint lithography (NIL). Nanoimprint lithography is a technique that can be used for building a plurality of waveguides within a photonic wafer-scale interposer (PWSI). The plurality of waveguides built on or within the PWSI is used to send data as optical data between chiplets bonded to a front side of the PWSI. The optical data can include serial optical data. The optical data is based on light emitted from a plurality of photonic communication devices. The plurality of photonic communication devices includes a plurality of surface-emitting light sources. The surface-emitting light sources can include VCSELs, LEDs, laser diodes, and the like. The emitted light is coupled to waveguides within the plurality of waveguides using optical couplers such as mirrors, gratings, and so on. The waveguides can be used to transfer the emitted light across the PWSI. The transferring light enables transferring data between chiplets within a plurality of chiplets bonded to a front side of the PWSI. The transferring data is enabled by waveguides based on nanoimprint lithography on a photonic wafer-scale interposer.

The FIG. 600 shows an example of nanoimprint lithography (NIL). The NIL can include a stamp 610 for fabricating a plurality of waveguides within the PWSI. In embodiments, the fabricating includes creating a stamp, wherein the stamp includes one or more topological patterns, wherein the one or more topological patterns correspond to the plurality of waveguides. The stamp can be based on hard materials such as silicon, silicon dioxide, nickel, or other hard materials. The stamp can be based on soft materials such as polydimethylsiloxane (PDMS) or other soft polymers that can be cured using ultraviolet (UV) light. The waveguide building includes a substrate 620 onto which a photoresist 622 is deposited. The resist can include a polymer. The stamp is used to create an impression in the photoresist on the substrate. Embodiments comprise compressing 630, by the stamp, photoresist deposited on the PWSI, wherein the compressing results in one or more topological patterns in the photoresist. The topological patterns in the photoresist can be used to indicate where the plurality of waveguides can be formed within the PWSI. The stamp can be removed. The photoresist can be cured following the compression. In a usage example, the photoresist can be cured using ultraviolet (UV) light. In embodiments, the compressing includes heating the photoresist. The heating the photoresist can harden or cure portions of the photoresist while leaving other portions of the photoresist uncured. The uncured photoresist can be removed from the substrate.

The building of the plurality of waveguides can include using the cured photoresist as bases for the waveguides. The building the nanoimprinted waveguides can continue with forming reflective surfaces. Embodiments further comprise coating the one or more topological patterns, wherein the coating results in a cladding of the first waveguide. Materials that can be used to create the reflective surface can include silver, aluminum alloys, and so on. Alternatively, the building of the waveguides can include using the cured photoresist to control etching the substrate. Embodiments comprise etching 640 the PWSI. The etching can be based on a “wet” etch such as a liquid etch, a “dry” etch such as a plasma etch, and so on. A dry etch can include using a plasma of reactive gases that can remove unprotected material (e.g., material not covered by the photoresist) from the substrate. In the figure, an example etched area 642 is shown. Following the etching, the remaining, cured photoresist can be removed 650 from the substrate. The result of removing the photoresist from the substrate reveals the plurality of nanoimprinted waveguides 660. The NIL steps can be repeated. Various shapes can be made into a waveguide, a coupler (such as a grating coupler), and so on.

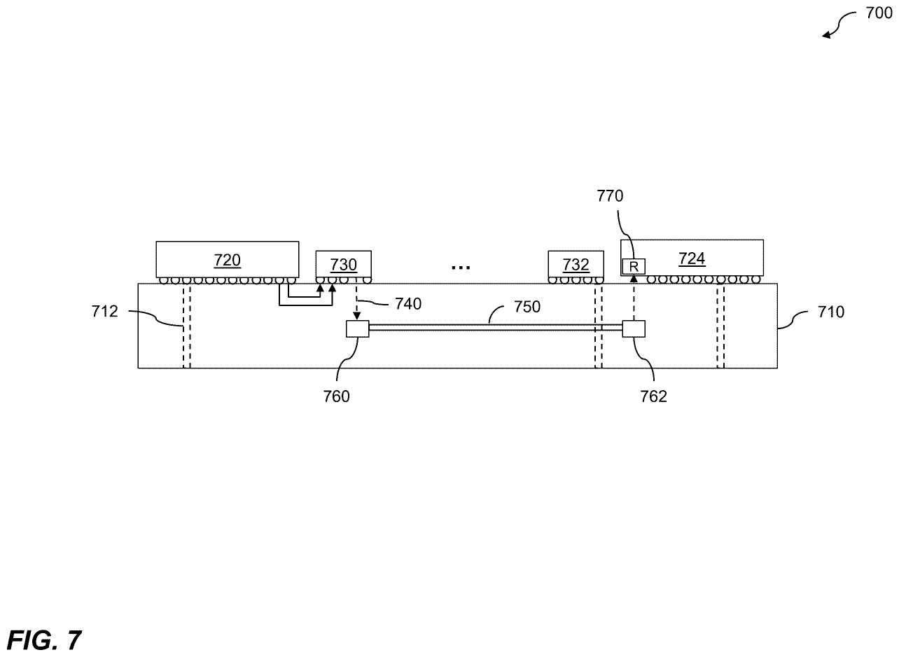

FIG. 7 is a cross-section of a photonic wafer-scale interposer (PWSI). The PWSI includes waveguides based on nanoimprint lithography. In order to improve interconnection bandwidth and/or speed, chiplets such as switching chiplets, AI chiplets, surface-emitting light sources, and so on can be bonded to a front side of a photonic-scale integration interposer (PWSI). The PWSI shown in illustration 700 includes one or more photonic elements such as photonic communication devices. The PWSI further includes a plurality of waveguides. A waveguide within the PWSI can enable coupling between any number of chiplets bonded to the PWSL The waveguides can be used to transfer data as optical signals between chiplets. Coupling between the chiplets and the waveguides is accomplished by one or more photonic communication devices, such as a first photonic communication device. In embodiments, the first photonic communication device comprises a surface-emitting light source. In some embodiments, the first photonic communication device comprises a vertical-cavity surface-emitting laser (VCSEL).

Data such as serial electronic data from a chiplet can be sent to a VCSEL. The VCSEL can translate the electronic data into light (e.g., optical data) and emit the light vertically into the PWSI. A first optical coupler can couple the light from the VCSEL to a waveguide which can convey the light any distance across the PWSL To accommodate longer paths, the waveguides can be manufactured via nanoimprint lithography. In embodiments, the fabricating does not include reticle stitching. The “far” end of the waveguide can comprise a second optical coupler. The second optical coupler can couple the light from the waveguide to an optical receiver which can convert the optical data to electrical data. The optical receiver can be a device that is separate from the second chiplet, can be within the second chiplet, and so on. Thus, high bandwidth, high speed photonic communication is enabled across the PWSI using waveguides based on nanoimprint lithography.

A front side of the PWSI is bonded to a plurality of chiplets. The chiplets can be connected, attached, bonded, or otherwise coupled to the PWSI 710. In illustration 700, chiplet 720 and chiplet 724 are bonded to the front side of the PWSL Any number of chiplets that can fit on the PWSI can be added. The chiplets can include AI accelerators, switching chiplets, ASICS, I/O chiplets, and so on. The chiplets can be bonded to the PWSI with micro-bumps, controlled collapse chip connections (C4s), and so on. The bonding can be accomplished via laser-assisted bonding or another bonding method, such as a flip-chip application. The PWSI can include a plurality of through-silicon vias (TSVs) such as TSV 712. A TSV can include an electrical connection that passes completely through a wafer such as a silicon wafer, a glass wafer, or a die. The plurality of TSVs can be oriented vertically in order to enable connections between the front side of the wafer and the back side of the wafer. A chiplet can be coupled to a light source, such as a surface-emitting light source. In embodiments, the surface-emitting light source comprises a vertical-cavity surface-emitting laser (VCSEL). The surface-emitting light source can also include a light emitting diode (LED), a laser diode (LID), etc. Other light sources also can be used. The PWSI can include one or more surface-emitting light sources such as VCSEL 730 and VCSEL 732.

Data is sent by a first chiplet to a second chiplet. The sending is based on a first waveguide such as waveguide 750 within the plurality of waveguides on the PWSL The waveguide can include one or more confinement regions, such as a high confinement region, a low confinement region, and so on. The waveguide can include a transition between confinement regions associated with the waveguide. The transition can include an adiabatic tapering of the waveguide. The second chiplet, such as chiplet 724, can receive the data that was sent. Data from the sending (e.g., first) chiplet can be converted from electrical data, which can be serialized electrical data, to optical data. The optical data can be sent via the waveguide and reconverted to electrical data to be received by the receiving (e.g., second) chiplet. In a usage example, the sending includes transmitting the data, by the first chiplet, to a first surface-emitting light source within one or more surface-emitting light sources. The electrical data can be converted to optical data using the surface-emitting light source, such as VCSEL 730.

In order to couple light from a surface-emitting light source to a waveguide, the light is conveyed to an optical coupler. Optical information is conveyed 740, from the first surface-emitting light source 730, to a first optical coupler 760. The first optical coupler couples the optical information, which is based on the data sent from the first chiplet, to the first waveguide 750. The first coupler can be based on one or more coupling techniques. In embodiments, the first optical coupler comprises a grating coupler. In a second usage example, the first optical coupler can include an off-axis diffractive lens. In a further usage example, the first optical coupler can include a bent waveguide. The first optical coupler can include a mirror such as a mirror built by a nanoimprint lithography (NIL) process. The grating coupler can operate on light that has been pre-angled, where the pre-angled light, when impinging on the grating coupler, can enter a waveguide at an angle substantially normal to the inlet aperture of the waveguide. Embodiments further comprise angling the light that was emitted by the first photonic communication device, wherein the angling is based on a micro-optical element (MOE). The MOE can be coupled to the first photonic communication device in order to angle the emitting light. In a usage example, the MOE can be placed over or near the laser opening of a VCSEL. In a usage example, the MOE can include a micro lens, a diffractive optical element, a Fresnel lens, an asymmetric non-focusing optical device, and so on.

The second chiplet 724 can receive the data that was sent. The receiving can include coupling the optical information, using a second optical coupler 762, from the first waveguide to an optical receiver. The second optical coupler can be based on one or more receiving techniques. The second optical coupler can comprise a grating coupler. The grating coupler can diffract light at specific frequencies, input angles, etc. to enable efficient transfer of light out of a waveguide within the PWSI. The second optical coupler can comprise a photodiode. The photodiode can convert the optical data to digital data. The data received at the optical coupler can be transferred. The data can be transferred by the optical receiver to the second chiplet. The data can be transferred as optical data or transferred as digital data. The data can be received at the second chiplet by a receiver 770. If the receiver receives optical data, the receiver can convert the optical data to digital data. If the receiver receives digital data, the digital data can be used as received, converted from serial data to parallel data, and so on.

Embodiments further include coupling, to the back side of the PWSI, a plurality of modular power substrates (MPSs) (not shown). The MPSs can be further coupled to a plurality of DC-to-DC converters (not shown). The plurality of DC-to-DC converters can comprise a unified control board (UCB). The coupling of the MPSs to the PWSI can be achieved by a number of techniques. The MPSs can be bonded to a back side of the PWSI by laser-assisted bonding (LAB). The LAB can create localized heat at points, by one or more lasers, on the PWSI where the MPSs are bonded to the PWSI The bonding can be accomplished using solder balls such as microbumps, controlled collapse chip connections (C4s), ball grid arrays (BGAs), and so on. The bonding of the MPSs to the PWSI can include bonding the MPSs to one or more through-silicon vias (TSVs) such as TSV 712. The laser-assisted bonding is able to create heat at the solder balls, without heating the PWSI, using a reflow soldering technique. Heating the PWSI using a reflow technique can cause previously soldered connections to reflow and potentially disconnect or short, damage diffusions, damage waveguides, and so on.

Alternatively, the MPSs can be coupled to a back side of the PWSI via one or more elastomer sheets (not shown). The one or more elastomer sheets can comprise a conductive filament, such as brass, gold, etc., embedded in a silicone rubber sheet, or another suitable material. The filaments can be embedded on a pitch. The pitch can be designed to match a connector array, such as a ball grid array (BGA), of the MPS. The elastomer sheet can be held in place with a compression force which can be delivered by one or more compression plates (not shown). An adhesive backing can be added to the elastomer sheet. When one or more filaments come in contact with a C4, contact can be made between the C4 of the MPS and a solder bump, microbump, or C4 associated with the PWSL. One or more filaments can make contact with one or more TSVs. Once coupled to the back side of the PWSI, The MPSs can send power to the chiplets.

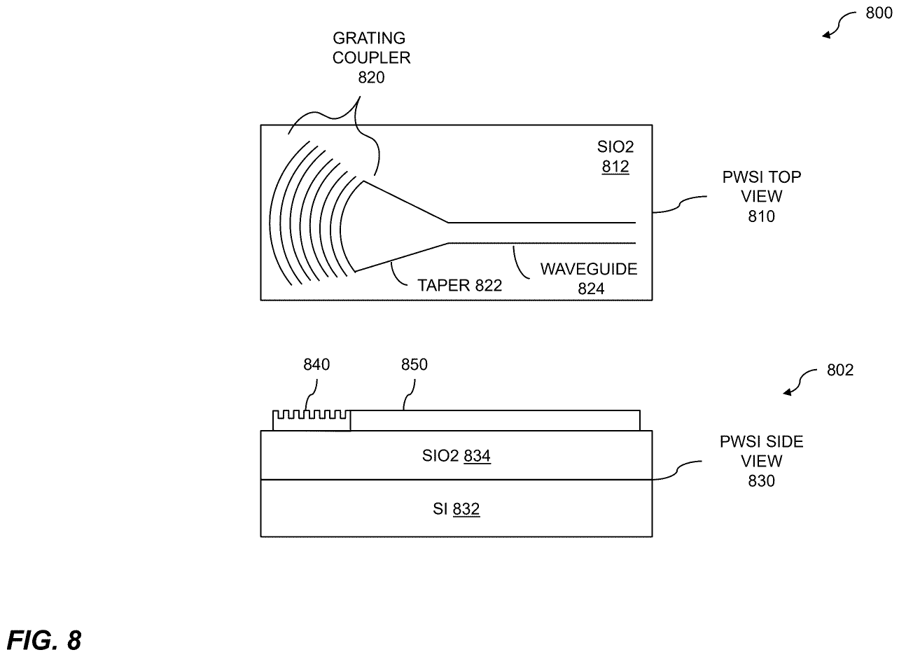

FIG. 8 is a diagram of a grating coupler. The figure includes a top view and a side view of the grating coupler. Described previously and throughout, light that is emitted by a photonic communication device such as a surface-emitting light source can be coupled to a waveguide using a grating coupler. The grating coupler can be “tuned” to an angle, a polarization, a wavelength of light, such as 850 nm, etc. to enable a substantial portion of the emitted light to be coupled to a waveguide. The waveguide can include a waveguide within a plurality of waveguides, where the plurality of waveguides can be within a photonic wafer-scale interposer (PWSI). In embodiments, the plurality of waveguides is fabricated using nanoimprint lithography (NIL). The waveguide can be used to send data as optical data between a first chiplet and second chiplet, where the first chiplet and the second chiplet can be bonded to a front side of the PWSI. The optical data that is sent can be converted from digital data such as serial digital data by a surface-emitting light source. The optical data can be detected using a device such as a photodiode, a photo Darlington, and so on. The grating coupler enables transferring data using a waveguide based on nanoimprint lithography on a photonic wafer-scale interposer.

A top view of a grating coupler 800 is shown. The grating couple can be formed within a photonic wafer-scale interposer (PWSI) 810. The grating coupler can be formed with standard lithography techniques, NIL, or another fabrication process. The PWSI can include an insulation layer such as an SiO2 insulation layer 812. A grating coupler 820 can be formed on the SiO2 layer. The grating coupler can include a periodic structure as shown. The period structure can “focus” light directed at the grating coupler toward a taper 822. The taper can transfer light into a waveguide 824. The grating coupler can be based on diffraction. The grating coupler can enable a substantial portion of light directed toward the grating coupler to be directed into the waveguide. Further, a sideview of the grating coupler formed on a PWSI 830 is shown 802. The PWSI can include a silicon (Si) wafer 832. An oxide layer (SiO2) 834 can be formed on the Si wafer. In turn, a grating coupler 840 can be formed on the oxide layer. The grating coupler can receive light at an angle from a first light source (not shown). Recall that a first photonic communication device can emit light. In embodiments the first photonic communication device comprises a surface-emitting light source. In some embodiments, the first photonic communication device comprises a vertical-cavity surface-emitting laser (VCSEL). The surface-emitting light source can further include an LED, a laser diode, and the like. Light from the VCSEL can be angled using a diffractive optical element (DOE) (not shown). The DOE can include a micro lens, a Fresnel lens, an asymmetric non-focusing optical device, etc. The DOE can couple a portion of the emitted light that can be angled toward the grating coupler into a waveguide. In the FIG. 802, the waveguide can include waveguide 850.

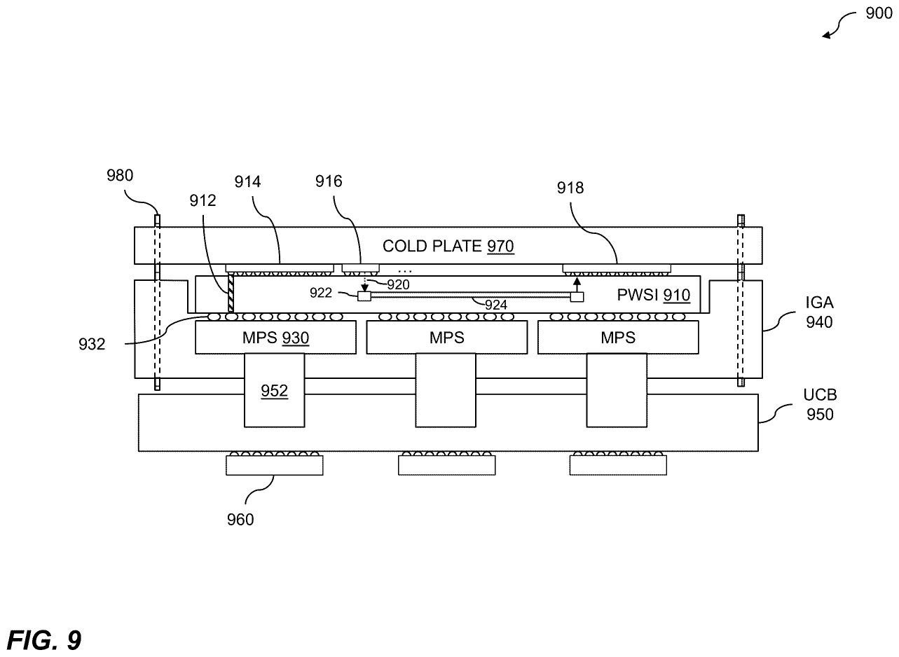

FIG. 9 is an apparatus for transferring data. The transferring data can be accomplished using waveguides based on nanoimprint lithography on a photonic wafer-scale interposer (PWSI). The transferring data can be further accomplished using back side power delivery. Various electronic and photonic elements can be attached, bonded, mounted, or otherwise coupled to the photonic wafer-scale interposer (PWSI). The electronic elements can include chiplets such as AI accelerators based on AI chiplets, network switches based on switching chiplets, memories, and so on. The photonic elements can include photonic communication devices such as VCSELs, LEDs, laser diodes, photodiodes, and the like. Power such as DC power can be sent by a universal control board (UCB) to a plurality of chiplets and other electronic and photonic elements. The sending can be accomplished using a plurality of DC-to-DC converters, a plurality of modular power substrates (MPSs), and a plurality of through-silicon vias (TSVs). The plurality of photonic elements, chiplets, etc. can be bonded to a front side of a photonic wafer-scale interposer (PWSI). The plurality of MPSs can be coupled to a back side of the PWSI. The MPSs can also be coupled to the UCB based on a plurality of high-power sockets. The UCB can further include a plurality of DC-to-DC power converters. The coupling can be aided by an isometric grid array (IGA). The wafer can be stiffened using a grid such as an isometric grid array (IGA) in order to protect the wafer from the weight of the flipped chips and other elements. The IGA can enable planar compression of the MPS to the PWSI. The planar compression can be based on the one or more spring-loaded fasteners. The planar compression can be based on one or more clamps. The planar compression can enable consistent coupling via adhesion, coupling, compressing, etc. of the MPSs to a back side of the PWSI.

An apparatus for transferring data is disclosed comprising: a photonic wafer-scale interposer (PWSI), wherein the PWSI includes a plurality of waveguides, wherein the plurality of waveguides is fabricated using a nanoimprint lithography (NIL) process; a plurality of chiplets, wherein the plurality of chiplets is bonded to a front side of the PWSI, and wherein the plurality of chiplets includes a plurality of photonic communication devices; a first chiplet within the plurality of chiplets, wherein the first chiplet sends data to a first photonic communication device within the plurality of photonic communication devices, wherein the first photonic communication device emits light toward a first optical coupler, and wherein the emitted light is based on the data that was sent; a first waveguide within the plurality of waveguides, wherein the emitted light is coupled to the first waveguide, wherein the first waveguide comprises a first distance, wherein the first distance is greater than an exposure, on the PWSI, of a single photomask reticle; and a second chiplet within the plurality of chiplets, wherein the second chiplet receives data that was sent by the first chiplet based on light that was coupled to the first waveguide.

The apparatus 900 comprises a photonic wafer-scale interposer (PWSI) 910, wherein the PWSI includes a plurality of waveguides, wherein the plurality of waveguides is fabricated using a nanoimprint lithography (NIL) process. The plurality of waveguides is used to enable high-speed communication between and among various elements that can be bonded, attached, or otherwise coupled to the PWSI. In embodiments, the fabricating includes creating a stamp, wherein the stamp includes one or more topological patterns, wherein the one or more topological patterns correspond to the plurality of waveguides. The stamp can be used to form patterns in photoresist. Embodiments include compressing, by the stamp, photoresist deposited on the PWSI, wherein the compressing results in the one or more topological patterns in the photoresist. The apparatus 900 includes a plurality of through silicon vias (TSVs), such as TSV 912. The plurality of through-silicon vias (TSVs) associated with the PWSI can be used to provide connections between a front side of the PWSI and a back side of the PWSI. The PWSI can be used to achieve wafer-scale integration (WSI). The WSI is enabled by waveguides based on a nanoimprint lithography on a photonic wafer-scale interposer. The PWSI can be used to couple various elements such as electrical elements, optical elements, electro-optical elements, photonic elements, and so on. The PWSI can further provide interconnections among the coupled elements, and waveguides within the PWSI, to transfer optical data. The PWSI can include inorganic materials or organic materials. In a usage example, the PWSI can include a silicon interposer. Micro-bumps discussed above can be used to couple the one or more chiplets, such as chiplet 914, to the front side of the PWSI.

The apparatus 900 includes a plurality of chiplets, wherein the plurality of chiplets is bonded to a front side of the PWSI, and wherein the plurality of chiplets includes a plurality of photonic communication devices. The plurality of chiplets can include chiplet 914, which can be a first chiplet. The plurality of chiplets can include processing chiplets, memory chiplets, AI accelerator chiplets for an optical wafer-scale AI accelerator, switching chiplets for an optical wafer-scale network switch, and so on. The plurality of photonic communication devices can include surface-emitting light sources, optical detectors, and so on. The apparatus 900 can include a first photonic communication device 916. The first photonic communication device can include a first surface-emitting light source. In embodiments, the first photonic communication device comprises a vertical-cavity surface-emitting laser (VCSEL). The VCSEL can be deposited on the front side of the PWSI based on micro transfer printing. The VCSEL is coupled to the PWSI. The apparatus can include other surface-emitting light sources such as light emitting diodes (LEDs), laser diodes (LDs), etc. The surface-emitting light source can be used to transfer data between the first chiplet and the second chiplet. The surface-emitting light source can be used to convert digital data such as serial digital data to optical data. The optical data can include serial optical data.

The chiplets that can be coupled to the PWSI can include one or more chips that can accomplish a processing function such as a deep learning function, a natural language function, a network switching function, and so on. The chiplets can include an integrated circuit designed for a flip-chip application. In embodiments, the PWSI comprises an optical wafer-scale AI accelerator, wherein one or more chiplets within the plurality of chiplets comprise one or more artificial intelligence (AI) accelerators. The PWSI can be configured for other processing, networking, and further applications. In embodiments, the PWSI comprises an optical wafer-scale network switch, wherein one or more chiplets within the plurality of chiplets comprise one or more switching chiplets. In a usage example, the plurality of chiplets can include one or more I/O chiplets.

The apparatus 900 includes a first chiplet 914 within the plurality of chiplets, wherein the first chiplet sends data to a first photonic communication device 916 within the plurality of photonic communication devices, wherein the first photonic communication device emits light toward a first optical coupler, and wherein the emitted light is based on the data that was sent. Noted previously, the first photonic communication device can include a surface-emitting light source such as a VCSEL, an LED, a LD, and so on. Communications between the chiplets and the photonic communications devices can be accomplished via metal layers on and within the interposer. In a usage example, the data that was sent is based on one or more metal layers within the PWSI. Use of wiring within the PWSI can reduce latency and electrical parasitics such as resistance, capacitance, and inductance, and enables improvement of signal integrity and/or bandwidth, etc. The light emitted by the first surface-emitting light source is conveyed 920 from the light source to a first optical coupler 922. The first optical coupler can include a lens such as a microlens, a diffractive lens such as a Fresnel lens, a grating, a mirror, and so on.

The apparatus 900 includes a first waveguide 924 within the plurality of waveguides, wherein the emitted light is coupled to the first waveguide, wherein the first waveguide comprises a first distance, wherein the first distance is greater than an exposure, on the PWSI, of a single photomask reticle. The first coupler couples the light from the light source coupled by the optical coupler to a first waveguide 924. The first waveguide that receives the light coupled from the light source includes a waveguide fabricated using nanoimprint lithography. As explained above and throughout, nanoprint lithography can be useful for fabricating long waveguides that extend beyond the reach, on the wafer, of a single reticle. Noted above, the fabrication includes creating a stamp, wherein the stamp includes one or more topological patterns, wherein the one or more topological patterns correspond to a waveguide within the plurality of waveguides. The stamp can be compressed into photoresist that was deposited on the PWSI, thereby transferring the topological patterns to the photoresist.

A micro-optical element (MOE) can be coupled to each surface-emitting light source within the plurality of photonic communications devices. The MOE can be used in conjunction with the nanoimprinted waveguide. The MOE can be coupled to the first surface-emitting light source. Light that is emitted can be angled based on a micro-optical element (MOE). The MOE can include a micro lens, a diffractive optical element such as a Fresnel lens, an asymmetric non-focusing optical device, etc. In a usage example, the angling can be based on a location of each surface-emitting light source, where the angling can compensate for a cross-wafer variation. The angling can further enable coupling of the emitted light to the first optical coupler. The apparatus 900 includes a second chiplet within the plurality of chiplets, wherein the second chiplet receives data that was sent by the first chiplet based on light that was coupled to the first waveguide. The second chiplet can include chiplet 918.

The apparatus 900 can include a plurality of modular power substrates (MPSs), wherein the plurality of MPSs is coupled to a back side of the PWSI. An example MPS 930 is shown. Each MPS can be coupled to the back side of the PWSI. Each MPS within the plurality of MPSs can include a connector or a socket for coupling the MPS to other components associated with the apparatus. The socket can include a socket on a unified control board (UCB) (described below). The socket can comprise a high-power socket, a high voltage socket, and so on. The connector or socket can include one or more plugs, pins, terminals, contacts, etc. from the UCB which can be inserted into a socket. In a usage example, the coupling can be based on a high voltage socket. The high voltage socket can transfer power from the UCB to the plurality of MPSs. The high voltage socket can be used to provide a first DC voltage. The first DC voltage can be provided by a DC-to-DC converter. The first DC voltage can be converted to a second DC voltage by one or more DC-to-DC converters.

The apparatus 900 can include an isometric grid array (IGA) 940. Each MPS within the plurality of MPS can be inserted into the IGA. The IGA can enable support of and stiffening of the photonic wafer-scale interposer. The IGA can support and planarize the PWSI, thereby preventing the PWSI from fracturing. The IGA can include a plurality of reinforcement structures. Each reinforcement structure in the plurality of reinforcement structures can enable planar compression of elastomer sheets which can couple the MPSs to the back side of the PWSI. The elastomer sheets can include a plurality of filaments that can form an electrical coupling between a front side of the elastomer sheet and a back side of the elastomer sheet. Alternatively, the example connections can include solder bumps such as micro bumps, C4s 932, a ball grid array (BGA), etc. The solder bumps can be soldered using a laser-assisted bonding (LAB) technique.

The apparatus 900 can include a unified control board (UCB) 950. The UCB can comprise a plurality of DC-to-DC power converters. The UCB can be coupled to the plurality of MPSs. The coupling the UCB to the plurality of MPSs can be accomplished using a socket such as socket 952. The plurality of DC-to-DC converters can include a DC-to-DC converter 960. The DC-to-DC converters are coupled to the UCB based on a plurality of sockets, plugs, solder balls, etc. The UCB can send DC power to the plurality of chiplets bonded to the PWSI. The sending can be based on the plurality of MPSs and the plurality of TSVs, such as TSV 912. The socket can comprise the socket on the UCB. The socket can comprise a high-power socket, a high voltage socket, and so on. The coupling can include one or more plugs, pins, terminals, contacts, etc. from the UCB which can be inserted into the socket. In a usage example, the coupling can be based on a high voltage socket, wherein the high voltage socket transfers power from the UCB to the plurality of MPSs. The high voltage socket can be used to provide a first DC voltage that can be converted to a second DC voltage by one or more DC-to-DC converters. The mechanical coupling can accommodate a maximum lateral displacement of the UCB due to thermal expansion during operation. In a usage example, the mechanical coupling can include a compliant connector. The lateral displacement can result from thermal expansion of the PWSI, the UCB, and/or the MPS during operation.

The UCB 950 can include a digital controller chip (not shown). The DC-to-DC converters can be controlled by a control chip associated with the UCB. The digital controller chip can control power delivery to the plurality of functional chips. The controlling power delivery can include enabling or disabling power transfer, controlling an input voltage to an output voltage from a DC-to-DC converter, and the like. A usage example can include matching each DC-to-DC power converter within the plurality of DC-to-DC power converters included on the UCB to one or more respective MPSs in the plurality of MPSs. DC power from a DC-to-DC converter can be sent to an MPS via an interconnect on the UCB. DC power can be fed to the DC-to-DC converters. The control signals can enable and disable elements such as controller chips and DC-to-DC converters, can provide instructions to controller chips, etc.

The apparatus 900 can include a cold plate 970. The cold plate can be coupled to one or more chiplets, photonic communication devices such as surface-emitting light sources, etc. The cold plate can be mounted to the isometric grid array (IGA). The cold plate can be used to extract a portion of heat generated by chiplets, photonic communication devices, and other elements such as the functional chiplets, etc. Recall that prodigious amounts of heat can be generated by chips and other electronic elements as they are operating. This point can be particularly relevant to high-performance chips, and the generated heat can be attenuated through the use of a cold plate. The mounting of the cold plate to a grid such as the IGA can be accomplished using clips, screws, bolts, clamps, and so on. For the apparatus, the cold plate can be mounted to the IGA using spring-loaded fasteners 980, clamps, and so on.

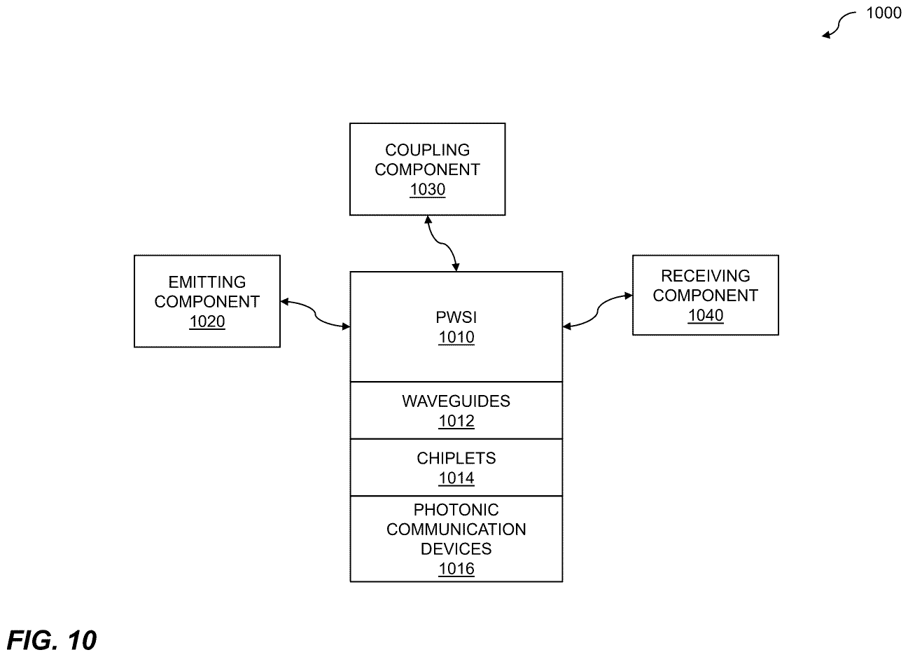

FIG. 10 is a system diagram for waveguides based on nanoimprint lithography on a photonic wafer-scale interposer. A plurality of waveguides can be formed, within the PWSI, that enables high-speed communication between and among chiplets bonded to a front side of the PWSI. Data that is transferred between the chiplets can include electronic data such as serial electronic data. The electronic data can be converted to optical data by sending the electronic data from a first chiplet to a first photonic communication device. The first photonic communication device can include a first surface-emitting light source. The surface-emitting light source can include a VCSEL. The surface-emitting light source converts the electronic data to optical data. The sending includes emitting light by the surface-emitting light source toward a first optical coupler. The first optical coupler can include a mirror, a lens, a grating, a curved waveguide, and so on and is built by a nanoimprint lithography (NIL) process. The emitted light is coupled by the optical coupler to a first waveguide in the plurality of waveguides. The plurality of waveguides is fabricated by a nanoimprint lithography (NIL) process. The first waveguide within the plurality of waveguides comprises a first distance, wherein the first distance is greater than an exposure, on the PWSI, of a single photomask reticle. The light that is sent from the first chiplet via the waveguide is received by a second chiplet. The received data is transferred to the second chiplet, thereby completing the transfer of data between two chiplets via a waveguide.

A plurality of waveguides is fabricated, using a nanoimprint lithography (NIL) process, within a photonic wafer-scale interposer (PWSI), wherein a first waveguide within the plurality of waveguides comprises a first distance, wherein the first distance is greater than an exposure, on the PWSI, of a single photomask reticle. The fabricating includes creating a stamp, wherein the stamp includes one or more topological patterns, wherein the one or more topological patterns correspond to the plurality of waveguides. Photoresist deposited on the PWSI is compressed by the stamp, wherein the compressing results in the one or more topological patterns in the photoresist. A plurality of chiplets is bonded to a front side of the PWSI, wherein the plurality of chiplets includes a plurality of photonic communication devices. The plurality of photonic communication devices includes surface-emitting light sources. Each surface-emitting light source within the plurality of surface-emitting light sources can include a vertical-cavity surface-emitting laser (VCSEL), a light emitting diode (LED), a laser diode (LD), etc. Light is emitted, by a first photonic communication device within the plurality of photonic communication devices, toward a first optical coupler, wherein the emitting is based on data sent from a first chiplet in the plurality of chiplets. The data that was sent can include serial data. Electronic data from the first chiplet is converted to optical data by a first surface-emitting light source. The light that was emitted is coupled, by the first optical coupler, to the first waveguide. As discussed, the first optical coupler can include a mirror, a grating, and so on. The first waveguide includes a nanoimprint lithography mirror. The data that was sent by the first chiplet is received by a second chiplet within the plurality of chiplets, wherein the receiving is based on light that was coupled to the first waveguide.

Disclosed is a system for transferring data comprising: a photonic wafer-scale interposer (PWSI); a plurality of waveguides within the PWSI, wherein the plurality of waveguides is fabricated by a nanoimprint lithography (NIL) process, wherein a first waveguide within the plurality of waveguides comprises a first distance, wherein the first distance is greater than an exposure, on the PWSI, of a single photomask reticle; a plurality of chiplets, wherein the plurality of chiplets is bonded to a front side of the PWSI; and a plurality of photonic communication devices within the plurality of chiplets, wherein the system is configured to: emit light, by a first photonic communication device within the plurality of photonic communication devices, toward a first optical coupler, wherein the emitted light is based on data sent from a first chiplet in the plurality of chiplets; couple, by the first optical coupler, light that was emitted, to the first waveguide; and receive, by a second chiplet within the plurality of chiplets, data that was sent by the first chiplet, wherein the receiving is based on light that was coupled to the first waveguide.

The system 1000 includes a photonic wafer-scale interposer (PWSI) 1010. The PWSI can be coupled to a variety of electronic and photonic elements to obtain wafer-scale integration. The wafer-scale integration can be used to perform a variety of computationally intensive tasks such as handling large datasets, AI model processing, network switching, and so on. The system 1000 includes a plurality of waveguides 1012 within the PWSI, wherein the plurality of waveguides is fabricated by a nanoimprint lithography (NIL) process, wherein a first waveguide within the plurality of waveguides comprises a first distance, wherein the first distance is greater than an exposure, on the PWSI, of a single photomask reticle. A photomask reticle can be a highly precise pattern for a layer of the PWSI. The photomask reticle can be advanced across a wafer such as the PWSI in a “step and repeat” technique. The first distance of the first waveguide is greater than can be exposed by the photomask reticle. The plurality of waveguides can be used to provide high speed communication of data, processed data, control signals, instructions, and so on between and among chiplets bonded to the PWSI. The waveguides associated with the PWSI can include tapered waveguides. The tapering can include adiabatic tapering. Light that represents data such as serial data can be coupled to a waveguide. The coupling can be accomplished using a mirror, a grating, a lens, and so on. In embodiments, the NIL comprises a full-wafer nanoimprint process. The NIL process can include creating a stamp that can be used to compress photoresist deposited on the PWSI. The photoresist can be heated, and the PWSI can be etched. Embodiments comprise coating the one or more topological patterns, wherein the coating results in a cladding of the first waveguide.

The system 1000 comprises a plurality of chiplets 1014, wherein the plurality of chiplets is bonded to a front side of the PWSI. The chiplets can include processor chiplets, memory chiplets, AI accelerator chiplets, switching chiplets, and the like. The system 1000 comprises a plurality of photonic communication devices 1016 within the plurality of chiplets. The photonic communication devices can include surface-emitting light sources, optical couplers that can include photodiodes, and so on. The surface-emitting light sources can emit light that can be coupled by an optical coupler into one or more waveguides. In embodiments, the first photonic communication device comprises a vertical-cavity surface-emitting laser (VCSEL). Other surface-emitting light sources can also be used. In a usage example, a surface-emitting light source can include a light emitting diode (LED), a laser diode (LD), and so on. A micro-optical element (MOE) can be coupled to each surface-emitting light source within the plurality of surface-emitting light sources. The MOE can include a microlens, a grating, and so on. Embodiments include angling the light that was emitted by the first photonic communication device, wherein the angling is based on a micro-optical element (MOE). The angling by the MOE can be based on a location of each surface-emitting light source, wherein the angling compensates for a cross-wafer variation. The cross-wafer variation can include wafer warpage.

The system 1000 includes an emitting component 1020. The emitting component 1020 is configured to emit light, by a first photonic communication device within the plurality of photonic communication devices, toward a first optical coupler, wherein the emitted light is based on data sent from a first chiplet in the plurality of chiplets. The emitted light is used to send data from a first chiplet to a second chiplet. The first photonic communication device can include a VCSEL, an LED, an LD, and so on. The first optical coupler couples the emitted light into a first waveguide (discussed below). The first optical coupler can include a mirror, a grating, a curved waveguide, and the like. The data can be sent by the first chiplet to the first photonic communication device (e.g., a VCSEL) using one or more metal layers of the PWSI. The metal layers, which enable interconnection between and among chiplets and other elements, can be fabricated on or within the PWSI. Using the metal layers offers significant inter-chiplet communication speed due to short wire lengths, and reduced “parasitics” such as resistance, capacitance, and inductance. The first photonic communication device can emit light based on the sent data. The emitted light represents the data as optical data. The light is emitted toward an optical coupler within the PWSI. Due to the cross-wafer variations discussed above, an MOE can angle the emitted light to compensate for the cross-wafer variations.

The system 1000 includes a coupling component 1030. The coupling component 1030 is configured to couple, by the first optical coupler, light that was emitted, to the first waveguide. Light that was emitted by the first photonic communication device such as a VCSEL can be coupled to the first waveguide using a first optical coupler. In embodiments, the first optical coupler comprises a grating coupler. The first optical coupler can direct the light emitted by the first photonic communication device into an inlet aperture of the waveguide. The first waveguide includes a waveguide fabricated using a nanoimprint lithography (NIL) process. The system 1000 includes a receiving component 1040. The receiving component 1040 is configured to receive, by a second chiplet within the plurality of chiplets, data that was sent by the first chiplet, wherein the receiving is based on light that was coupled to the first waveguide. The receiving can be accomplished optically, electronically, and so on. In a usage example, the receiving can include further coupling the light that was coupled to the first waveguide, by a second optical coupler, from the first waveguide, to an optical receiver. The receiver can include an optical receiver, an electronic receiver, and the like. In a usage example, the second optical coupler comprises a photodiode. The photodiode can convert the optical data received from the waveguide to electronic data. The received data can be transferred to the second chiplet.

Each of the above methods may be executed on one or more processors on one or more computer systems. Embodiments may include various forms of distributed computing, client/server computing, and cloud-based computing. Further, it will be understood that the depicted steps or boxes contained in this disclosure's flow charts are solely illustrative and explanatory. The steps may be modified, omitted, repeated, or re-ordered without departing from the scope of this disclosure. Further, each step may contain one or more sub-steps. While the foregoing drawings and description set forth functional aspects of the disclosed systems, no particular implementation or arrangement of software and/or hardware should be inferred from these descriptions unless explicitly stated or otherwise clear from the context. All such arrangements of software and/or hardware are intended to fall within the scope of this disclosure.

The block diagram and flow diagram illustrations depict methods, apparatus, systems, and computer program products. The elements and combinations of elements in the block diagrams and flow diagrams show functions, steps, or groups of steps of the methods, apparatus, systems, computer program products and/or computer-implemented methods. Any and all such functions generally referred to herein as a “circuit,” “module,” or “system” may be implemented by computer program instructions, by special-purpose hardware-based computer systems, by combinations of special purpose hardware and computer instructions, by combinations of general-purpose hardware and computer instructions, and so on.

A programmable apparatus which executes any of the above-mentioned computer program products or computer-implemented methods may include one or more microprocessors, microcontrollers, embedded microcontrollers, programmable digital signal processors, programmable devices, programmable gate arrays, programmable array logic, memory devices, application specific integrated circuits, or the like. Each may be suitably employed or configured to process computer program instructions, execute computer logic, store computer data, and so on.

It will be understood that a computer may include a computer program product from a computer-readable storage medium and that this medium may be internal or external, removable and replaceable, or fixed. In addition, a computer may include a Basic Input/Output System (BIOS), firmware, an operating system, a database, or the like that may include, interface with, or support the software and hardware described herein.

Embodiments of the present invention are limited to neither conventional computer applications nor the programmable apparatus that run them. To illustrate: the embodiments of the presently claimed invention could include an optical computer, quantum computer, analog computer, or the like. A computer program may be loaded onto a computer to produce a particular machine that may perform any and all of the depicted functions. This particular machine provides a means for carrying out any and all of the depicted functions.

Any combination of one or more computer readable media may be utilized including but not limited to: a non-transitory computer readable medium for storage; an electronic, magnetic, optical, electromagnetic, infrared, or semiconductor computer readable storage medium or any suitable combination of the foregoing; a portable computer diskette; a hard disk; a random access memory (RAM); a read-only memory (ROM); an erasable programmable read-only memory (EPROM, Flash, MRAM, FeRAM, or phase change memory); an optical fiber; a portable compact disc; an optical storage device; a magnetic storage device; or any suitable combination of the foregoing. In the context of this document, a computer readable storage medium may be any tangible medium that can contain or store a program for use by or in connection with an instruction execution system, apparatus, or device.

It will be appreciated that computer program instructions may include computer executable code. A variety of languages for expressing computer program instructions may include without limitation C, C++, Java, JavaScript™, ActionScript™, assembly language, Lisp, Perl, Tcl, Python, Ruby, hardware description languages, database programming languages, functional programming languages, imperative programming languages, and so on. In embodiments, computer program instructions may be stored, compiled, or interpreted to run on a computer, a programmable data processing apparatus, a heterogeneous combination of processors or processor architectures, and so on. Without limitation, embodiments of the present invention may take the form of web-based computer software, which includes client/server software, software-as-a-service, peer-to-peer software, or the like.

In embodiments, a computer may enable execution of computer program instructions including multiple programs or threads. The multiple programs or threads may be processed approximately simultaneously to enhance utilization of the processor and to facilitate substantially simultaneous functions. By way of implementation, any and all methods, program codes, program instructions, and the like described herein may be implemented in one or more threads which may in turn spawn other threads, which may themselves have priorities associated with them. In some embodiments, a computer may process these threads based on priority or other order.

Unless explicitly stated or otherwise clear from the context, the verbs “execute” and “process” may be used interchangeably to indicate execute, process, interpret, compile, assemble, link, load, or a combination of the foregoing. Therefore, embodiments that execute or process computer program instructions, computer-executable code, or the like may act upon the instructions or code in any and all of the ways described. Further, the method steps shown are intended to include any suitable method of causing one or more parties or entities to perform the steps. The parties performing a step, or portion of a step, need not be located within a particular geographic location or country boundary. For instance, if an entity located within the United States causes a method step, or portion thereof, to be performed outside of the United States, then the method is considered to be performed in the United States by virtue of the causal entity.

While the invention has been disclosed in connection with preferred embodiments shown and described in detail, various modifications and improvements thereon will become apparent to those skilled in the art. Accordingly, the foregoing examples should not limit the spirit and scope of the present invention; rather it should be understood in the broadest sense allowable by law.

What is claimed is:

1. A method for transferring data comprising:
fabricating, using a nanoimprint lithography (NIL) process, a plurality of waveguides within a photonic wafer-scale interposer (PWSI), wherein a first waveguide within the plurality of waveguides comprises a first distance, wherein the first distance is greater than an exposure, on the PWSI, of a single photomask reticle;
bonding, to a front side of the PWSI, a plurality of chiplets, wherein the plurality of chiplets includes a plurality of photonic communication devices;
emitting light, by a first photonic communication device within the plurality of photonic communication devices, toward a first optical coupler, wherein the emitting is based on data sent from a first chiplet in the plurality of chiplets;
coupling, by the first optical coupler, the light that was emitted, to the first waveguide; and
receiving, by a second chiplet within the plurality of chiplets, data that was sent by the first chiplet, wherein the receiving is based on light that was coupled to the first waveguide.

2. The method of claim 1 wherein the first chiplet and the second chiplet are separated, on the PWSI, by substantially the first distance.

3. The method of claim 1 wherein the fabricating does not include reticle stitching.

4. The method of claim 1 wherein the first photonic communication device comprises a surface-emitting light source.

5. The method of claim 4 wherein the first photonic communication device comprises a vertical-cavity surface-emitting laser (VCSEL).

6. The method of claim 1 wherein the first photonic communication device comprises a ring resonator.

7. The method of claim 1 wherein the NIL process comprises a full-wafer nanoimprint process.

8. The method of claim 7 wherein the fabricating includes creating a stamp, wherein the stamp includes one or more topological patterns, wherein the one or more topological patterns correspond to the plurality of waveguides.

9. The method of claim 8 further comprising compressing, by the stamp, photoresist deposited on the PWSI, wherein the compressing results in the one or more topological patterns in the photoresist.

10. The method of claim 9 wherein the compressing includes heating the photoresist.

11. The method of claim 9 further comprising etching the PWSI.

12. The method of claim 9 further comprising coating the one or more topological patterns, wherein the coating results in a cladding of the first waveguide.

13. The method of claim 1 wherein the bonding includes coupling the first photonic communication device to the PWSI, wherein the coupling is based on micro-transfer printing.

14. The method of claim 1 wherein the first optical coupler comprises a grating coupler.

15. The method of claim 14 further comprising angling the light that was emitted by the first photonic communication device, wherein the angling is based on a micro-optical element (MOE).

16. The method of claim 1 wherein the receiving includes further coupling the light that was coupled to the first waveguide, by a second optical coupler, from the first waveguide, to an optical receiver.

17. The method of claim 16 wherein the second optical coupler comprises a photodiode.

18. The method of claim 16 further comprising transferring, by the optical receiver, the data to the second chiplet.

19. The method of claim 1 wherein the PWSI comprises an optical wafer-scale AI accelerator, wherein one or more chiplets within the plurality of chiplets comprise one or more artificial intelligence (AI) accelerators.

20. The method of claim 1 wherein the PWSI comprises an optical wafer-scale network switch, wherein one or more chiplets within the plurality of chiplets comprise one or more switching chiplets.

21. The method of claim 1 further comprising providing power to the plurality of chiplets, wherein the providing is based on a back side of the PWSI, and wherein the PWSI includes a plurality of through-silicon vias (TSVs).

22. The method of claim 21 further comprising coupling, to the back side of the PWSI, a plurality of modular power substrates (MPSs).

23. The method of claim 22 further comprising coupling the plurality of MPSs to a unified control board (UCB), wherein the coupling is based on a plurality of sockets, and wherein the UCB includes a plurality of DC-to-DC power converters.

24. The method of claim 23 further comprising delivering DC power, by the UCB, to the plurality of chiplets, wherein the delivering is based on the plurality of DC-to-DC power converters, the plurality of MPSs, and the plurality of TSVs, and wherein the delivering includes a first voltage conversion.

25. The method of claim 24 further comprising transferring the DC power from the UCB, by the plurality of MPSs, to the plurality of chiplets, wherein the transferring includes a second voltage conversion.

26. An apparatus for transferring data comprising:
a photonic wafer-scale interposer (PWSI), wherein the PWSI includes a plurality of waveguides, wherein the plurality of waveguides is fabricated using a nanoimprint lithography (NIL) process;
a plurality of chiplets, wherein the plurality of chiplets is bonded to a front side of the PWSI, and wherein the plurality of chiplets includes a plurality of photonic communication devices;
a first chiplet within the plurality of chiplets, wherein the first chiplet sends data to a first photonic communication device within the plurality of photonic communication devices, wherein the first photonic communication device emits light toward a first optical coupler, and wherein the emitted light is based on the data that was sent;
a first waveguide within the plurality of waveguides, wherein the emitted light is coupled to the first waveguide, wherein the first waveguide comprises a first distance, wherein the first distance is greater than an exposure, on the PWSI, of a single photomask reticle; and
a second chiplet within the plurality of chiplets, wherein the second chiplet receives data that was sent by the first chiplet based on light that was coupled to the first waveguide.

27. The apparatus of claim 26 wherein the first photonic communication device comprises a vertical-cavity surface-emitting laser (VCSEL).

28. A system for transferring data comprising:
a photonic wafer-scale interposer (PWSI);
a plurality of waveguides within the PWSI, wherein the plurality of waveguides is fabricated by a nanoimprint lithography (NIL) process, wherein a first waveguide within the plurality of waveguides comprises a first distance, wherein the first distance is greater than an exposure, on the PWSI, of a single photomask reticle;
a plurality of chiplets, wherein the plurality of chiplets is bonded to a front side of the PWSI; and
a plurality of photonic communication devices within the plurality of chiplets, wherein the system is configured to:
emit light, by a first photonic communication device within the plurality of photonic communication devices, toward a first optical coupler, wherein the emitted light is based on data sent from a first chiplet in the plurality of chiplets;
couple, by the first optical coupler, light that was emitted, to the first waveguide; and
receive, by a second chiplet within the plurality of chiplets, data that was sent by the first chiplet, wherein the receiving is based on light that was coupled to the first waveguide.
